(19) United States
(12) Patent Application Publication
(10) Pub. No.: US 2026/0214905 A1
(43) Pub. Date: Jul. 23, 2026

(54) MEMORY DEVICE HAVING THREE-DIMENSIONAL STRUCTURE AND METHOD OF OPERATING THE SAME

(71) Applicant: SAMSUNG ELECTRONICS CO., LTD., Suwon-si (KR)

(72) Inventor: Juhyung KIM, Suwon-si (KR)

(73) Assignee: SAMSUNG ELECTRONICS CO., LTD., Suwon-si (KR)

(21) Appl. No.: 19/446,113

(22) Filed: Jan. 12, 2026

(30) Foreign Application Priority Data
Jan. 22, 2025 (KR) 10-2025-0009823

(51) Int. Cl. H10B 43/35; G11C 5/06; G11C 13/00; G11C 16/04; H10B 41/10; H10B 41/27; H10B 41/35; H10B 41/41; H10B 43/10; H10B 43/27; H10B 43/40; H10B 51/10; H10B 51/20; H10B 51/30; H10B 51/40; H10B 63/00; H10D 30/68; H10D 30/69; H10D 62/80; H10N 70/00; H10W 80/00; H10D 30/01; H10D 64/60

(52) U.S. Cl. CPC H10B 43/35; G11C 5/063; G11C 13/0007; G11C 16/0483; H10B 41/10; H10B 41/27; H10B 41/35; H10B 41/41; H10B 43/10; H10B 43/27; H10B 43/40; H10B 51/10; H10B 51/20; H10B 51/30; H10B 51/40; H10B 63/34; H10B 63/84; H10D 30/689; H10D 30/693; H10D 30/701; H10D 62/875; H10N 70/826; H10W 80/312; H10D 30/0411; H10D 30/0413; H10D 30/0415; H10D 64/60

(57) ABSTRACT

Provided is a memory device including: a peripheral circuit structure; and a cell array structure on the peripheral circuit structure, wherein the cell array structure includes: gate electrodes spaced apart in a vertical direction; a channel layer passing through the gate electrodes, wherein the channel layer includes an oxide semiconductor and is in a vertical opening extending in the vertical direction; a back-side electrode layer extending in the vertical direction in the vertical opening, wherein the back-side electrode layer is on a side wall of the channel layer; a conductive interfacial layer extending in the vertical direction in the vertical opening, wherein the conductive interfacial layer is between the side wall of the channel layer and the back-side electrode layer; and a bit line pad on the side wall of the channel layer in the vertical opening and spaced apart from the back-side electrode layer in the vertical direction.

### CROSS-REFERENCE TO RELATED APPLICATION

This application is based on and claims priority to Korean Patent Application No. 10-2025-0009823, filed on January 22, 2025, in the Korean Intellectual Property Office, the disclosure of which is incorporated by reference herein in its entirety.

### BACKGROUND

The disclosure relates to a memory device having a three-dimensional structure and a method of operating the memory device, and more particularly, to a memory device having a memory string arranged in a vertical direction and a method of operating the memory device.

In an electronic system requiring data storage, a memory device capable of storing a large amount of data is required. As one of the methods of increasing the data storage capacity of a memory device, a memory device including three-dimensionally arranged memory cells, instead of two-dimensionally arranged memory cells, has been proposed. It is required to ensure the operational reliability of three-dimensional memory cells with increased integration.

### SUMMARY

Provided is a memory device having improved operation characteristics and improved integration.

Further provided is a method of operating a memory device which may improve the operational reliability of the memory device.

According to an aspect of the disclosure, a memory device includes: a peripheral circuit structure; and a cell array structure on the peripheral circuit structure, wherein the cell array structure comprises: gate electrodes spaced apart in a vertical direction; a channel layer passing through the gate electrodes, wherein the channel layer comprises an oxide semiconductor and is in a vertical opening extending in the vertical direction; a back-side electrode layer extending in the vertical direction in the vertical opening, wherein the back-side electrode layer is on a side wall of the channel layer; a conductive interfacial layer extending in the vertical direction in the vertical opening, wherein the conductive interfacial layer is between the side wall of the channel layer and the back-side electrode layer; and a bit line pad on the side wall of the channel layer in the vertical opening and spaced apart from the back-side electrode layer in the vertical direction.

According to an aspect of the disclosure, a memory device includes: a peripheral circuit structure; and a cell array structure on the peripheral circuit structure, wherein the cell array structure comprises: gate electrodes spaced apart in a vertical direction; a storage structure passing through the gate electrodes, wherein the storage structure comprises a charge storage film and is in a vertical opening extending in the vertical direction; a channel layer on an inner wall of the storage structure in the vertical opening, the channel layer comprising an oxide semiconductor; a conductive interfacial layer on an inner wall of the channel layer in the vertical opening; a back-side electrode layer on an inner wall of the conductive interfacial layer in the vertical opening; and a bit line pad connected to a bottom portion of the channel layer in the vertical opening and spaced apart from the back-side electrode layer in the vertical direction.

According to an aspect of the disclosure, a memory device includes: a peripheral circuit structure; and a cell array structure on the peripheral circuit structure, wherein the cell array structure comprises: gate electrodes spaced apart in a vertical direction; a storage structure passing through the gate electrodes, wherein the storage structure comprises a charge storage film and is in a vertical opening extending in the vertical direction; a channel layer on an inner wall of the storage structure in the vertical opening, the channel layer comprising an oxide semiconductor; a conductive interfacial layer on an inner wall of the channel layer in the vertical opening; a back-side electrode layer on an inner wall of the conductive interfacial layer in the vertical opening; a bit line pad connected to a bottom portion of the channel layer in the vertical opening and spaced apart from the back-side electrode layer in the vertical direction; a spacer insulating layer on the inner wall of the channel layer in the vertical opening, wherein the spacer insulating layer is between the back-side electrode layer and the bit line pad and is between the conductive interfacial layer and the bit line pad; a bit line connected to the bit line pad; a common source line on an outer wall of an upper portion of the channel layer; a first connection via connected to the common source line; and a second connection via connected to the back-side electrode layer.

According to an aspect of the disclosure, there is provided a method of operating a memory device including a three-dimensional memory cell array, wherein the three-dimensional memory cell array includes a plurality of memory cell strings, the plurality of memory cell strings including a string selection transistor, a plurality of memory cell transistors, and a ground selection transistor, each memory cell string is connected to a bit line and a common source line, and each memory cell string is connected to a back-side electrode line disposed adjacent to channel regions of the plurality of memory cell transistors. The operating method includes erasing the plurality of memory cell strings, wherein the erasing includes applying a ground voltage to a word line connected to a memory cell string selected for erasing, floating a bit line connected to the selected memory cell string, and applying an erase voltage to a back-side electrode line connected to the selected memory cell string, wherein the erase voltage is a positive voltage.

In one or more embodiments, when the erase voltage is applied, a positive potential may be applied to the channel regions of the plurality of memory cell transistors of the selected memory cell string through the back-side electrode line.

In one or more embodiments, the three-dimensional memory cell array may include gate electrodes spaced apart in a vertical direction, a channel layer passing through the gate electrodes and extending in the vertical direction, a back-side electrode layer disposed on an inner wall of the channel layer and electrically connected to the back-side electrode line, and a bit line pad disposed on the inner wall of the channel layer, spaced apart from the back-side electrode layer, and electrically connected to the bit line.

In one or more embodiments, the erasing of the plurality of memory cell strings may include applying a positive potential to the channel layer disposed adjacent to the back-side electrode layer and providing holes into the channel layer.

In one or more embodiments, the three-dimensional memory cell array may further include a conductive interfacial layer disposed between the back-side electrode layer and the channel layer.

In one or more embodiments, the channel layer may include an oxide semiconductor, and the back-side electrode layer may include at least one of a metal, a metal nitride, a p-type oxide semiconductor, or p-type polysilicon.

In one or more embodiments, the erasing of the plurality of memory cell strings may further including floating a common source line connected to the selected memory cell string.

In one or more embodiments, the erasing may be performed in units of memory cell blocks, and the memory cell block may include a plurality of memory cell strings connected to a plurality of word lines stacked in the vertical direction.

In one or more embodiments, the operating method may further include programming the plurality of memory cell strings, wherein the programming includes floating a back-side electrode line connected to a memory cell transistor selected for programming, applying a ground voltage to a bit line connected to the selected memory cell transistor, and applying a program voltage to a word line connected to the selected memory cell transistor.

In one or more embodiments, the operating method may further include reading the plurality of memory cell strings, wherein the reading includes floating a back-side electrode line connected to a memory cell transistor selected for reading, applying a precharge voltage to a bit line connected to the selected memory cell transistor, applying a read level voltage to a word line connected to the selected memory cell transistor, changing a voltage of the precharged bit line according to a programming state of the selected memory cell transistor during a read evaluation time, and sensing the voltage of the bit line and reading data of the memory cell transistor according to a sensing result.

### BRIEF DESCRIPTION OF DRAWINGS

The above and other aspects and features of certain embodiments of the present disclosure will be more apparent from the following description taken in conjunction with the accompanying drawings, in which:

FIG. 1 is a block diagram illustrating a memory device, according to one or more embodiments;

FIG. 2 is a circuit diagram illustrating a memory block, according to one or more embodiments;

FIG. 3 is a perspective view illustrating a representative configuration of a memory device 100, according to one or more embodiments;

FIG. 4 is an enlarged layout view illustrating a portion A of FIG. 3;

FIG. 5 is a cross-sectional view taken along line B2-B2’ of FIG. 4;

FIG. 6 is an enlarged view illustrating a portion EN of FIG. 5;

FIG. 7 is a plan view at a first vertical level of FIG. 6;

FIG. 8 is a circuit diagram schematically illustrating a program operation of a memory device, according to one or more embodiments;

FIG. 9 is a circuit diagram schematically illustrating an erase operation of a memory device, according to one or more embodiments;

FIG. 10 is a circuit diagram schematically illustrating a read operation of a memory device, according to one or more embodiments;

FIG. 11 is a cross-sectional view illustrating a memory device, according to one or more embodiments;

FIG. 12 is an enlarged view illustrating the portion EN of FIG. 11;

FIG. 13 is a plan view at the first vertical level of FIG. 12;

FIG. 14 is a cross-sectional view illustrating a memory device, according to one or more embodiments;

FIG. 15 is an enlarged view illustrating the portion EN of FIG. 14;

FIG. 16 is a plan view at the first vertical level of FIG. 15;

FIG. 17 is a cross-sectional view illustrating a memory device, according to one or more embodiments;

FIG. 18 is a cross-sectional view illustrating a memory device, according to one or more embodiments;

FIG. 19 is an enlarged view illustrating the portion EN of FIG. 18;

FIG. 20 is a plan view at the first vertical level of FIG. 19;

FIG. 21 is a cross-sectional view illustrating a memory device, according to one or more embodiments;

FIGS. 22, 23A, 23B, 24A, 24B, 25A, 25B, 26A, 26B, 27A, 27B, 28 to 31, 32A, 32B and 33 are cross-sectional views illustrating a method of manufacturing a memory device, according to one or more embodiments;

FIG. 34 is a view schematically illustrating a data storage system including a memory device, according to one or more embodiments;

FIG. 35 is a perspective view schematically illustrating a data storage system including a memory device, according to one or more embodiments; and

FIG. 36 is a cross-sectional view schematically illustrating semiconductor packages, according to one or more embodiments.

### DETAILED DESCRIPTION

Hereinafter, embodiments will be described in detail with reference to the attached drawings.

In the following description, like reference numerals refer to like elements throughout the specification. Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

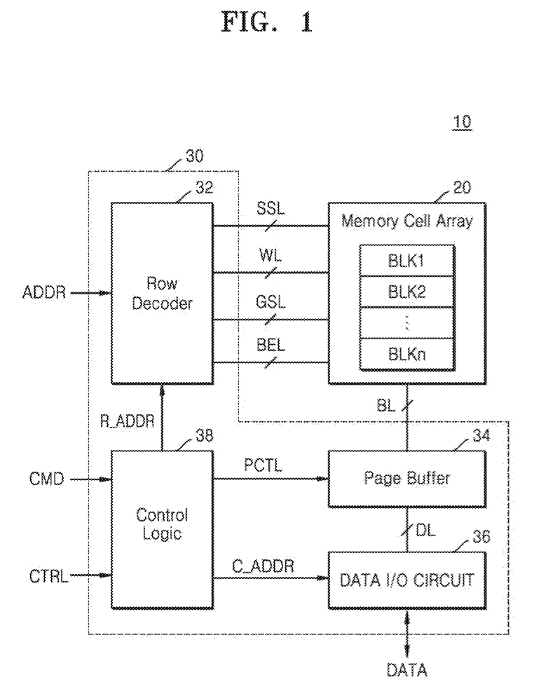

FIG. 1 is a block diagram illustrating a memory device 10, according to one or more embodiments.

Referring to FIG. 1, the memory device 10 may include a memory cell array 20 and a peripheral circuit 30. The memory cell array 20 includes a plurality of memory cell blocks BLK1, BLK2, ..., and BLKn. Each of the plurality of memory cell blocks BLK1, BLK2, ..., and BLKn may include a plurality of memory cells. The memory cell blocks BLK1, BLK2, ..., and BLKn may be connected to the peripheral circuit 30 through a bit line BL, a word line WL, a string selection line SSL, a ground selection line GSL, and a back-side electrode line BEL.

The peripheral circuit 30 may include a row decoder 32, a page buffer 34, a data input/output circuit 36, and a control logic 38. The peripheral circuit 30 may further include an input/output interface, a column logic, a voltage generator, a pre-decoder, a temperature sensor, a command decoder, an address decoder, and an amplification circuit.

The memory cell array 20 may be connected to the page buffer 34 through the bit line BL, and may be connected to the row decoder 32 through the word line WL, the string selection line SSL, the ground selection line GSL, and the back-side electrode line BEL. In the memory cell array 20, each of the plurality of memory cells included in the plurality of memory cell blocks BLK1, BLK2, ..., and BLKn may be a flash memory cell. The memory cell array 20 may include a three-dimensional (3D) memory cell array. The 3D memory cell array may include a plurality of NAND strings, and each NAND string may include a plurality of memory cells connected to a plurality of word lines WL stacked vertically on a substrate.

The peripheral circuit 30 may receive an address ADDR, a command CMD, and a control signal CTRL from the outside of the memory device 10 and may transmit and receive data DATA to and from a device outside the memory device 10.

The row decoder 32 may select at least one of the plurality of memory cell blocks BLK1, BLK2, ..., and BLKn in response to the address ADDR from the outside and may select the word line WL, the string selection line SSL, the ground selection line GSL, and the back-side electrode line BEL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation to apply a voltage according to the data DATA to be stored in the memory cell array 20 to the bit line BL, and may operate as a sense amplifier during a read operation to detect the data DATA stored in the memory cell array 20. The page buffer 34 may operate according to a control signal PCTL provided from the control logic 38.

The data input/output circuit 36 may be connected to the page buffer 34 through data lines DLs. During a program operation, the data input/output circuit 36 may receive the data DATA from a memory controller and may provide program data DATA to the page buffer 34 based on a column address C_ADDR provided from the control logic 38. During a read operation, the data input/output circuit 36 may provide, to the memory controller, read data DATA stored in the page buffer 34, based on the column address C_ADDR provided from the control logic 38.

The data input/output circuit 36 may transmit an input address or an instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and may provide the column address C_ADDR to the data input/output circuit 36. The control logic 38 may generate various internal control signals used in the memory device 10 in response to the control signal CTRL. For example, the control logic 38 may adjust a level of a voltage provided to the word line WL and the bit line BL during a memory operation such as a program operation or an erase operation.

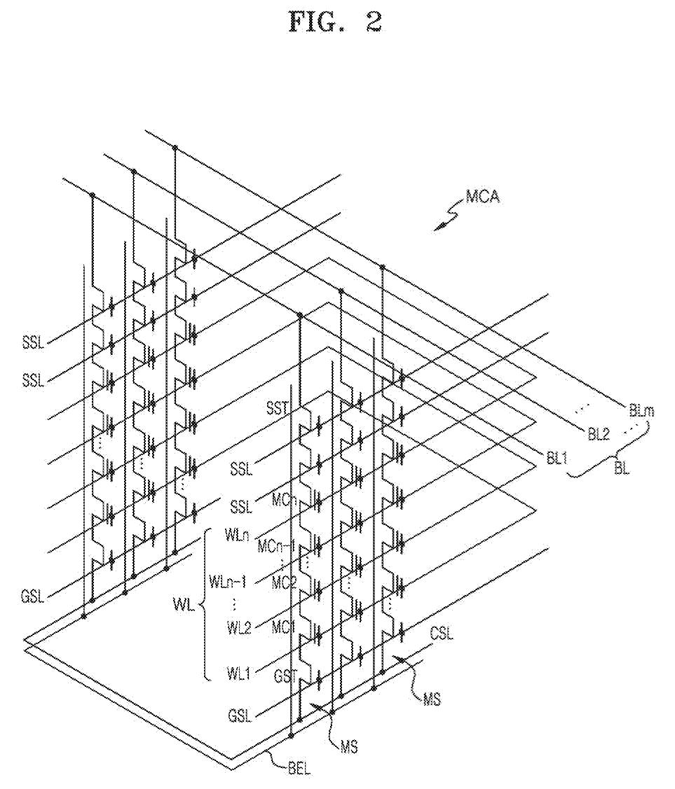

FIG. 2 is a circuit diagram illustrating a memory block BLK, according to one or more embodiments.

Referring to FIG. 2, a memory cell array MCA may include a plurality of memory cell strings MS. The memory cell array MCA may include a plurality of bit lines BL (BL1, BL2, …, and BLm), a plurality of word lines WL (WL1, WL2, …, WLn-1, and WLn), at least one string selection line SSL, at least one ground selection line GSL, and a common source line CSL. The plurality of memory cell strings MS may be formed between the plurality of bit lines BL (BL1, BL2, …, and BLm) and the common source line CSL. Although each of the plurality of memory cell strings MS includes two string selection lines SSL in FIG. 2, the disclosure is not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, …, MCn-1, and MCn. A drain region of the string selection transistor SST may be connected to the bit lines BL (BL1, BL2, …, and BLm), and a source region of the ground selection transistor GST may be connected to the common source line CSL. The common source line CSL may be an area where source regions of a plurality of ground selection transistors GST are commonly connected.

The string selection transistor SST may be connected to the string selection line SSL, and the ground selection transistor GST may be connected to the ground selection line GSL. The plurality of memory cell transistors MC1, MC2, …, MCn-1, and MCn may be respectively connected to the plurality of word lines WL (WL1, WL2, …, WLn-1, and WLn).

The plurality of memory cell strings MS may further include the back-side electrode line BEL. The back-side electrode line BEL may be disposed adjacent to channel regions of the plurality of memory cell transistors MC1, MC2, …, MCn-1, and MCn, and may be configured to apply a bias or a potential for a body erase effect to the channel regions of the plurality of memory cell transistors MC1, MC2, …, MCn-1, and MCn.

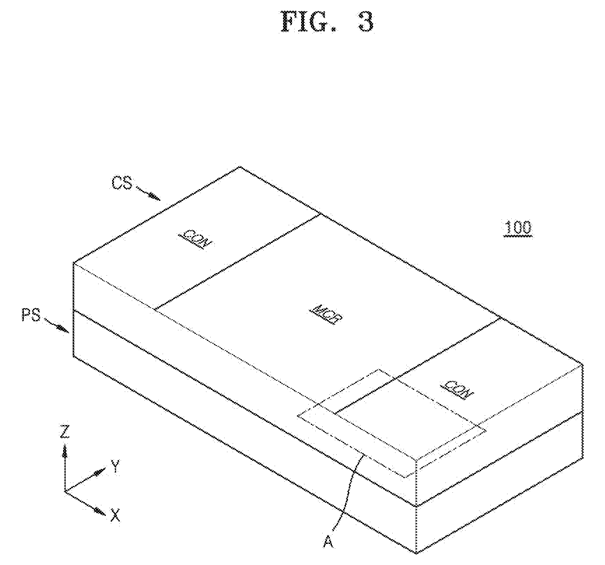

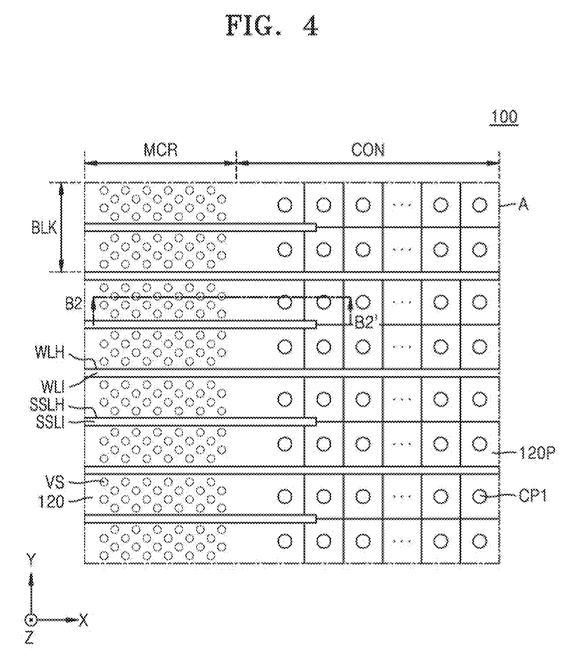

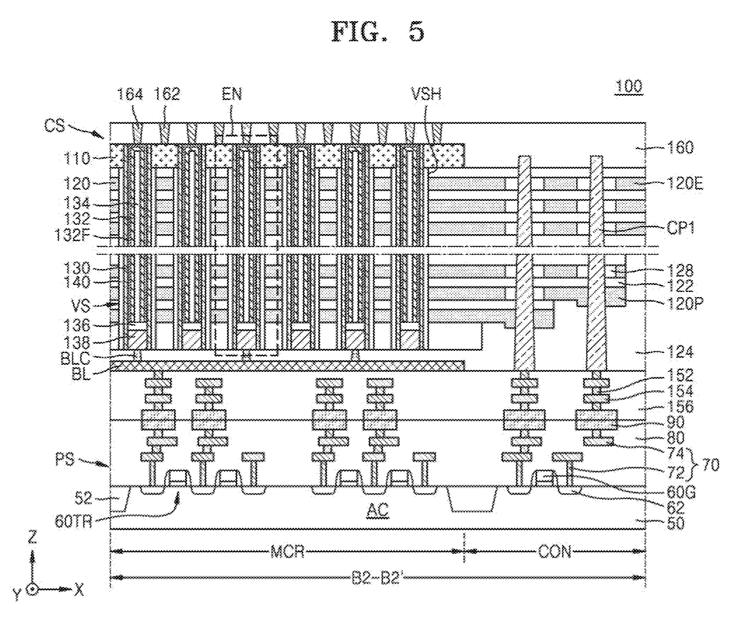

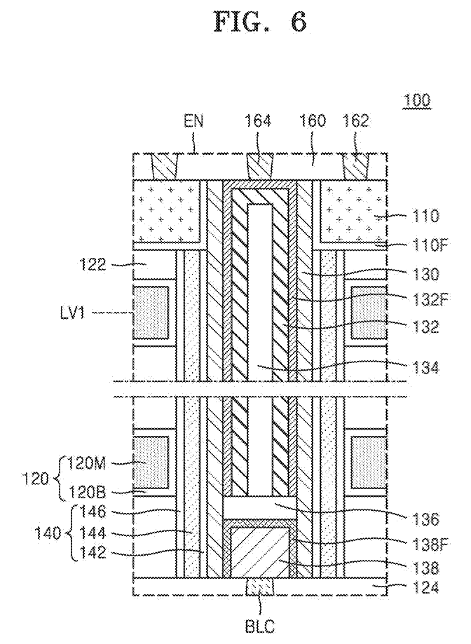

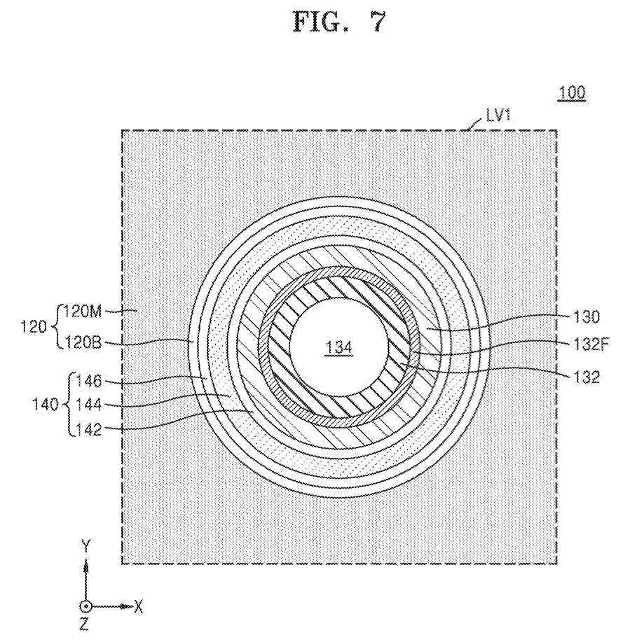

FIG. 3 is a perspective view illustrating a representative configuration of a memory device 100, according to one or more embodiments. FIG. 4 is an enlarged layout view illustrating a portion A of FIG. 3. FIG. 5 is a cross-sectional view taken along line B2-B2’ of FIG. 4. FIG. 6 is an enlarged view illustrating a portion EN of FIG. 5. FIG. 7 is a plan view at a first vertical level LV1 of FIG. 6.

Referring to FIGS. 3 to 7, the memory device 100 includes a cell array structure CS and a peripheral circuit structure PS overlapping each other in a vertical direction Z. The cell array structure CS may include the memory cell array 20 described with reference to FIG. 1, and the peripheral circuit structure PS may include the peripheral circuit 30 described with reference to FIG. 1.

The cell array structure CS may include a cell array area MCR and connection areas CON. The cell array area MCR may be disposed at a central portion of the cell array structure CS, and the connection areas CON may be disposed on both sides of the cell array area MCR.

The cell array area MCR may be an area where a plurality of memory cell blocks BLK are disposed. For example, each of a plurality of memory cell blocks BLK may include a plurality of vertical structures VS extending in the vertical direction Z. Each of the plurality of vertical structures VS may correspond to each of the memory cell strings MS described with reference to FIG. 2.

The connection area CON may be an area for providing electrical connection to the plurality of memory cell blocks BLK, and may be an area where a gate pad portion 120P electrically connected to each gate electrode 120 and a cell plug CP1 electrically connected to the gate pad portion 120P are disposed.

In one or more embodiments, the peripheral circuit structure PS may include a peripheral circuit configured to drive the plurality of memory cell blocks BLK. In one or more embodiments, a bottom surface of the cell array structure CS may be disposed on a top surface of the peripheral circuit structure PS, and as shown in FIG. 3, the cell array structure CS may be disposed at a higher vertical level than the peripheral circuit structure PS. In one or more embodiments, unlike in FIG. 3, a bottom surface of the peripheral circuit structure PS may contact a top surface of the cell array structure CS and the peripheral circuit structure PS may be disposed at a higher vertical level than the cell array structure CS.

As shown in FIG. 5, the peripheral circuit structure PS may include a peripheral circuit transistor 60TR and a peripheral circuit wiring structure 70 disposed on a substrate 50. An active area AC may be defined by a device isolation film 52 in the substrate 50, and a plurality of peripheral circuit transistors 60TR may be formed on the active area AC. The plurality of peripheral circuit transistors 60TR may include a peripheral circuit gate 60G, and source/drain regions 62 disposed on a portion of the substrate 50 on both sides of the peripheral circuit gate 60G.

The substrate 50 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The substrate 50 may be provided as a bulk wafer or an epitaxial layer. In another embodiment, the substrate 50 may include a silicon-on-insulator (SOI) substrate or a germanium-on-insulator (GeOI) substrate.

The peripheral circuit wiring structure 70 includes a plurality of peripheral circuit contacts 72 and a plurality of peripheral circuit wiring layers 74. An interlayer insulating film 80 covering the peripheral circuit transistor 60TR and the peripheral circuit wiring structure 70 may be disposed on the substrate 50. The plurality of peripheral circuit wiring layers 74 may have a multi-layer structure including a plurality of metal layers disposed at different vertical levels. A connection pad 90 may be disposed on the interlayer insulating film 80, and the peripheral circuit structure PS and the cell array structure CS may be electrically connected and bonded to each other by the connection pad 90.

The cell array structure CS may include a common source layer 110, the gate electrodes 120, and the vertical structure VS. The vertical structure VS may pass through the gate electrodes 120, may extend in the vertical direction Z, may be connected to the common source layer 110, and may include a channel layer 130, a back-side electrode layer 132, a conductive interfacial layer 132F, and a storage structure 140. In the connection area CON, an extending portion 120E and the gate pad portion 120P connected to the gate electrodes 120, and the cell plug CP1 passing through the extending portion 120E and the gate pad portion 120P and electrically connected to the gate pad portion 120P may be disposed. Insulating patterns 128 may be formed at positions vertically overlapping the gate pad portion 120P connected to the cell plug CP1, and the insulating patterns 128 may be disposed between the cell plug CP1 and the extending portions 120E.

In the cell array area MCR, the gate electrodes 120 may be spaced apart from each other in the vertical direction Z. The gate electrodes 120 and mold insulating layers 122 may be alternately arranged, and each mold insulating layer 122 may be disposed between two adjacent gate electrodes 120. In one or more embodiments, the mold insulating layer 122 may also be disposed on a bottom surface of a lowermost gate electrode 120, and the mold insulating layer 122 may also be disposed on a top surface of an uppermost gate electrode 120.

In one or more embodiments, the gate electrodes 120 may include a gate conductive layer 120M, and a barrier layer 120B conformally disposed on a top surface, a side wall, and a bottom surface of the gate conductive layer 120M. In one or more embodiments, the gate conductive layer 120M may include a metal such as tungsten, nickel, cobalt, or tantalum, a metal silicide such as tungsten silicide, nickel silicide, cobalt silicide, or tantalum silicide, doped polysilicon, or a combination thereof. In one or more embodiments, the barrier layer 120B may include at least one of aluminum oxide, aluminum silicon oxide, titanium nitride, or tantalum nitride. In one or more embodiments, the mold insulating layers 122 may include silicon oxide.

In one or more embodiments, the plurality of gate electrodes 120 may correspond to the ground selection line GSL, the word lines WL (WL1, WL2, …, WLn-1, and WLn), and at least one string selection line SSL constituting the memory cell string MS (see FIG. 2). For example, the uppermost gate electrode 120 may function as the ground selection line GSL, the lowermost gate electrode 120 may function as the string selection line SSL, and the remaining gate electrodes 120 may function as the word lines WL. Accordingly, the memory cell string MS in which the ground selection transistor GST, the string selection transistor SST, and the memory cell transistors MC1, MC2, …, MCn-1, and MCn between the ground selection transistor GST and the string selection transistor SST are connected in series may be provided. In one or more embodiments, at least one of the gate electrodes 120 may function as a dummy word line, but the disclosure is not limited thereto.

A stack separation insulating layer WLI may be disposed in a stack separation opening WLH passing through the gate electrodes 120 and the mold insulating layers 122 and extending in the vertical direction Z. As shown in FIG. 3, the gate electrodes 120 disposed between one pair of stack separation openings WLH may constitute one block BLK. Also, at least one gate electrode 120 (e.g., the lowermost gate electrode 120) in one block BLK may be separated into two gate electrodes 120 laterally spaced apart from each other by a string separation opening SSLH. A string separation insulating layer SSLI may be disposed in the string separation opening SSLH. The string separation insulating layer SSLI may be disposed between two gate electrodes 120 laterally spaced apart from each other in one block BLK.

Each of the plurality of vertical structures VS may pass through the gate electrodes 120 and the mold insulating layers 122 and may extend in the vertical direction Z. In one or more embodiments, each vertical structure VS may include the channel layer 130 extending in the vertical direction Z, the back-side electrode layer 132 disposed on an inner wall of the channel layer 130, the conductive interfacial layer 132F disposed between the inner wall of the channel layer 130 and the back-side electrode layer 132, and the storage structure 140 disposed on an outer wall of the channel layer 130. Each vertical structure VS may further include a buried insulating pillar 134, a spacer insulating layer 136, a bit line pad 138, and a pad interfacial layer 138F. The buried insulating pillar 134 may be partially or completely surrounded by the back-side electrode layer 132 and may extend in the vertical direction Z. The bit line pad 138 may be disposed on an inner wall of a bottom portion of the channel layer 130. The pad interfacial layer 138F may be disposed between the inner wall of the bottom portion of the channel layer 130 and the bit line pad 138. The spacer insulating layer 136 may be disposed between the bit line pad 138 and the buried insulating pillar 134.

In one or more embodiments, the channel layer 130 may be disposed in a vertical opening VSH passing through the gate electrodes 120 and the mold insulating layers 122 and extending in the vertical direction Z. The channel layer 130 may have a cylindrical shape extending in the vertical direction Z in the vertical opening VSH. The channel layer 130 may have a hollow pipe or tube shape extending in the vertical direction Z in the vertical opening VSH, and may have an annular or ring-like planar shape.

In one or more embodiments, the channel layer 130 may include an oxide semiconductor material. In one or more embodiments, the channel layer 130 may include at least one of indium gallium zinc oxide, indium aluminum zinc oxide, indium gallium oxide, indium zinc oxide, zinc oxide, zinc tin oxide, indium oxide, titanium oxide, tungsten oxide, or praseodymium chromium manganese oxide.

In one or more embodiments, the back-side electrode layer 132 may be disposed on the inner wall of the channel layer 130, and the conductive interfacial layer 132F may be disposed between the inner wall of the channel layer 130 and the back-side electrode layer 132. The conductive interfacial layer 132F and the back-side electrode layer 132 may each have a cylindrical shape extending in the vertical direction Z and having a closed top. For example, the back-side electrode layer 132 may be disposed on a top surface and a side wall of the buried insulating pillar 134, and the conductive interfacial layer 132F may be disposed on a top surface and a side wall of the back-side electrode layer 132.

In one or more embodiments, the back-side electrode layer 132 may correspond to the back-side electrode line BEL connected to the memory cell array 20 (see FIG. 1). In one or more embodiments, when an erase operation of the memory cell array 20 is performed, a positive potential may be transmitted into the channel layer 130 through the back-side electrode layer 132. In one or more embodiments, the back-side electrode layer 132 may include at least one of a metal, a metal nitride, a p-type oxide semiconductor, or p-type polysilicon. In one or more embodiments, the metal included in the back-side electrode layer 132 may include at least one of tungsten, molybdenum, niobium, nickel, cobalt, copper, palladium, platinum, ruthenium, iridium, gold, silver, chromium, rhodium, indium, tin, magnesium, zinc, beryllium, strontium, barium, or an alloy thereof, and the metal nitride may include at least one of titanium nitride, tantalum nitride, or tungsten nitride. In one or more embodiments, the p-type oxide semiconductor included in the back-side electrode layer 132 may include at least one of tin oxide, copper oxide, or nickel oxide.

In one or more embodiments, the conductive interfacial layer 132F may be an interfacial material layer for reducing contact resistance between the back-side electrode layer 132 and the channel layer 130. In one or more embodiments, the conductive interfacial layer 132F may include at least one of molybdenum oxide, indium oxide, tungsten oxide, tin oxide, indium tin oxide, indium tungsten oxide, titanium nitride, tantalum nitride, or tungsten nitride. In one or more embodiments, the conductive interfacial layer 132F may be omitted.

In one or more embodiments, the back-side electrode layer 132 may have a top surface located at a vertical level lower than or similar to that of a top surface of the channel layer 130 and disposed at a vertical level higher than that of a top surface of the uppermost gate electrode 120. The back-side electrode layer 132 may have a bottom surface disposed at a vertical level higher than that of a bottom surface of the channel layer 130 and lower than or equal to that of a bottom surface of the lowermost gate electrode 120.

In one or more embodiments, when an erase operation of a memory cell array is performed, an erase voltage (e.g., an erase voltage that is a positive voltage) may be applied to the back-side electrode layer 132, and a positive potential may be rapidly distributed and applied to an entire area or substantially an entire area of the channel layer 130 disposed at a vertical level corresponding to all of the gate electrodes 120 so that a relatively large amount of holes may be provided to the entire area or substantially the entire area of the channel layer 130. Accordingly, the erase operation may be rapidly and/or completely performed in the entire area of the channel layer 130.

In one or more embodiments, the bit line pad 138 may fill the inside of a bottom portion of the vertical opening VSH. In one or more embodiments, a top surface of the bit line pad 138 may be spaced apart from the bottom surface of the back-side electrode layer 132 in the vertical direction Z, and the spacer insulating layer 136 may be disposed between the top surface of the bit line pad 138 and the bottom surface of the back-side electrode layer 132.

In one or more embodiments, the bit line pad 138 may include at least one of a metal, a metal nitride, a p-type oxide semiconductor, or p-type polysilicon. In one or more embodiments, the metal included in the bit line pad 138 may include at least one of tungsten, molybdenum, niobium, nickel, cobalt, copper, palladium, platinum, ruthenium, iridium, gold, silver, chromium, rhodium, indium, tin, magnesium, zinc, beryllium, strontium, barium, or an alloy thereof, and the metal nitride may include at least one of titanium nitride, tantalum nitride, or tungsten nitride. In one or more embodiments, the p-type oxide semiconductor included in the bit line pad 138 may include at least one of tin oxide, copper oxide, or nickel oxide.

In one or more embodiments, the pad interfacial layer 138F may be disposed on the top surface and a side wall of the bit line pad 138. For example, the pad interfacial layer 138F may be disposed between the top surface of the bit line pad 138 and a bottom surface of the spacer insulating layer 136 and between the side wall of the bit line pad 138 and an inner wall of the channel layer 130.

In one or more embodiments, the pad interfacial layer 138F may be an interfacial material layer for reducing contact resistance between the bit line pad 138 and the channel layer 130. In one or more embodiments, the pad interfacial layer 138F may include at least one of molybdenum oxide, indium oxide, tungsten oxide, tin oxide, indium tin oxide, indium tungsten oxide, titanium nitride, tantalum nitride, or tungsten nitride. In one or more embodiments, the pad interfacial layer 138F may be omitted.

As shown in FIG. 5, the bit line pad 138 and the back-side electrode layer 132 may be spaced apart from each other in the vertical opening VSH, the spacer insulating layer 136 may be disposed between the bit line pad 138 and the back-side electrode layer 132, and a top surface of the spacer insulating layer 136 may contact a bottom surface of the buried insulating pillar 134. In one or more embodiments, the spacer insulating layer 136 and the buried insulating pillar 134 may be formed in the same manufacturing operation, and the spacer insulating layer 136 and the buried insulating pillar 134 may be integrally connected to each other and a boundary therebetween may not be visually discernible.

In one or more embodiments, the storage structure 140 may extend in the vertical direction Z on an outer wall of the channel layer 130. The storage structure 140 may have a structure including a tunneling insulating film 142, a charge storage film 144, and a blocking dielectric film 146 sequentially disposed on the outer wall of the channel layer 130. The storage structure 140 may constitute a memory element of a nonvolatile memory device that stores data by using a charge trap method.

The tunneling insulating film 142 may include silicon oxide, hafnium oxide, aluminum oxide, zirconium oxide, or tantalum oxide.

The charge storage film 144 is an area where electrons passing through the tunneling insulating film 142 from the channel layer 130 may be stored, and the charge storage film 144 may include silicon nitride, boron nitride, silicon boron nitride, or polysilicon doped with impurities. The blocking dielectric film 146 may be formed of silicon oxide, silicon nitride, or a metal oxide having a dielectric constant higher than that of silicon oxide. The metal oxide may include hafnium oxide, aluminum oxide, zirconium oxide, tantalum oxide, or a combination thereof.

In one or more embodiments, in the cell array area MCR, the common source layer 110 may partially or completely surround an outer wall of an upper portion of the channel layer 130. The common source layer 110 may be disposed at a higher vertical level than the gate electrodes 120, and a bottom surface of the common source layer 110 may contact a top surface of an uppermost mold insulating layer 122. In one or more embodiments, a top surface of the common source layer 110 may be coplanar with the top surface of the channel layer 130. In one or more embodiments, the back-side electrode layer 132 may be disposed on an inner wall of the upper portion of the channel layer 130 and the common source layer 110 may be disposed on the outer wall of the upper portion of the channel layer 130 so that the upper portion of the channel layer 130 is disposed between the back-side electrode layer 132 and the common source layer 110.

In one or more embodiments, the common source layer 110 may include polysilicon.

In one or more embodiments, an interfacial layer 110F may be disposed on the bottom surface and a side wall of the common source layer 110, and the interfacial layer 110F may be disposed between the channel layer 130 and the side wall of the common source layer 110 and between the uppermost mold insulating layer 122 and the bottom surface of the common source layer 110. In one or more embodiments, the interfacial layer 110F may be an interfacial material layer for reducing contact resistance between the common source layer 110 and the channel layer 130. In one or more embodiments, the interfacial layer 110F may include at least one of molybdenum oxide, indium oxide, tungsten oxide, tin oxide, indium tin oxide, indium tungsten oxide, titanium nitride, tantalum nitride, or tungsten nitride. In one or more embodiments, the interfacial layer 110F may be omitted.

The extending portion 120E and the gate pad portion 120P connected to the gate electrodes 120, and the cell plug CP1 electrically connected to the gate pad portion 120P, may be disposed in the connection area CON.

In one or more embodiments, the gate electrodes 120 may extend to the connection area CON, and portions of the gate electrodes 120 disposed in the connection area CON may be referred to as the extending portions 120E. The extending portions 120E may have horizontal lengths gradually increasing from a bottom surface of the cell array structure CS toward a top surface of the cell array structure CS. The extending portions 120E may have a stepped shape, and the gate pad portions 120P may be connected to ends of the extending portions 120E.

In one or more embodiments, as shown in FIG. 5, the gate pad portions 120P may have a greater thickness than the extending portions 120E in the vertical direction Z. In one or more embodiments, the gate pad portions 120P may have the same thickness as the extending portions 120E in the vertical direction Z.

In the connection area CON, a stack cover insulating layer 124 may be disposed on bottom surfaces of the gate electrodes 120, the extending portions 120E, and the gate pad portions 120P. The stack cover insulating layer 124 may be formed of a silicon oxide film, a silicon nitride film, SiON, SiOCN, SiCN, or a combination thereof.

In one or more embodiments, the cell plug CP1 may pass through the gate pad portion 120P and the extending portions 120E disposed on the gate pad portion 120P and may extend in the vertical direction Z. In this case, the insulating pattern 128 may be disposed between the cell plug CP1 and the extending portions 120E so that the cell plug CP1 is electrically connected to the gate pad portion 120P and is electrically insulated from the extending portions 120E disposed at a higher level than the gate pad portion 120P.

In one or more embodiments, unlike in FIG. 5, the extending portions 120E may have the same length in a horizontal direction, instead of having a stepped shape. In this case, the cell plugs CP1 having different lengths in the vertical direction Z may pass through the extending portions 120E, and a top surface of the cell plug CP1 may contact a bottom surface of the gate pad portion 120P. An insulating pattern 128 may be further disposed between the cell plug CP1 and the extending portions 120E so that the cell plug CP1 is electrically connected to the gate pad portion 120P and is electrically insulated from the extending portions 120E disposed under the gate pad portion 120P.

In the cell array area MCR, a bit line plug BLC may be disposed on a bottom surface of the vertical structure VS, and the bit line BL may be disposed on a bottom surface of the bit line plug BLC.

A connection via 152, a connection wiring layer 154, and an interlayer insulating film 156 partially or completely surrounding the connection via 152 and the connection wiring layer 154 may be disposed between the stack cover insulating layer 124 and the peripheral circuit structure PS. The connection via 152 and the connection wiring layer 154 may have a multi-layer structure to be disposed at a plurality of vertical levels, and may electrically connect the bit line BL and the cell plug CP1 to the peripheral circuit structure PS through the connection pad 90.

Although a metal-oxide boding type-memory device 100 in which the cell array structure CS and the peripheral circuit structure PS are attached to each other through the connection pad 90 is illustrated, the disclosure is not limited thereto. A memory device in which the cell array structure CS is directly disposed on the peripheral circuit structure PS without the use of the connection pad 90, or a bonding-type memory device in which the cell array structure CS and the peripheral circuit structure PS are attached to each other without the use of the connection pad 90 may be implemented.

In the cell array area MCR and the connection area CON, an upper insulating layer 160 may be disposed on a top surface of the common source layer 110 and a top surface of the mold insulating layer 122. A first connection via 162 may pass through the upper insulating layer 160 and may be connected to the common source layer 110, and a second connection via 164 may pass through the upper insulating layer 160 and may be connected to the back-side electrode layer 132 (in one or more embodiments, connected to the back-side electrode layer 132 via the conductive interfacial layer 132F). A common source voltage may be applied to the common source layer 110 through a wiring connected to the first connection via 162, and a voltage independent of the common source voltage may be applied to the back-side electrode layer 132 through a wiring connected to the second connection via 164.

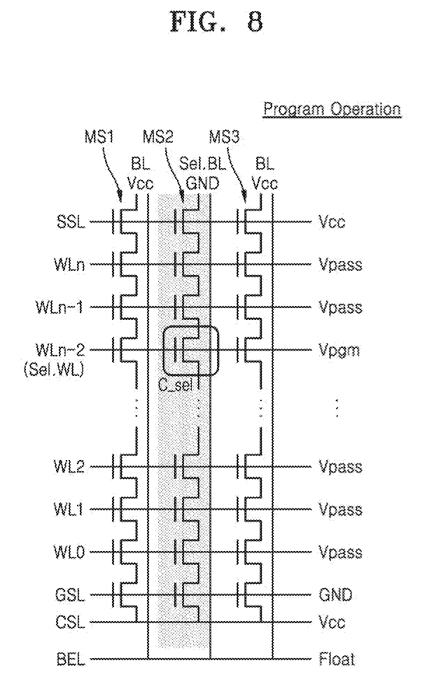

A method of driving the memory device 100 according to one or more embodiments will be described below with reference to FIGS. 8 to 11.

FIG. 8 is a circuit diagram schematically illustrating a program operation of a memory device, according to one or more embodiments.

Referring to FIG. 8, each of first to third memory strings MS1, MS2, and MS3 may include a plurality of memory cells connected to word lines WL0, WL1, WL2, ... WLn-2, WLn-1, and WLn, and each of the first to third memory strings MS1, MS2, and MS3 may further include a selection transistor connected to the ground selection line GSL and the string selection line SSL. Sources of selection transistors connected to the ground selection line GSL may be connected to the common source line CSL, and the back-side electrode line BEL may be connected along channels of the first to third memory strings MS1, MS2, and MS3.

In one or more embodiments, a program operation may be performed in units of pages for the plurality of memory cells. In the program operation, a power supply voltage Vcc may be applied to the string selection line SSL, a ground voltage GND may be applied to the ground selection line GSL, the power supply voltage Vcc may be applied to the common source line CSL, and the back-side electrode line BEL may be floated. A pass voltage Vpass may be applied to unselected word lines WL0, WL1, WL2, ... WLn-1, and WLn, and a program voltage Vpgm may be applied to a selected word line WLn-2.

The ground voltage GND may be applied to a bit line (e.g., a selected bit line Sel.BL) of the second memory string MS2, and the power supply voltage Vcc may be applied to the bit lines BL (e.g., unselected bit lines) of the first and third memory strings MS1 and MS3.

In the program operation, a memory cell C_sel disposed at an intersection between the selected word line WLn-2 and the selected bit line Sel.BL may be programmed. In one or more embodiments, when the memory cell C_sel is programmed, electrons may be tunneled from the channel layer 130 (see, e.g., FIG. 6) into the charge storage film 144 (see, e.g., FIG. 6).

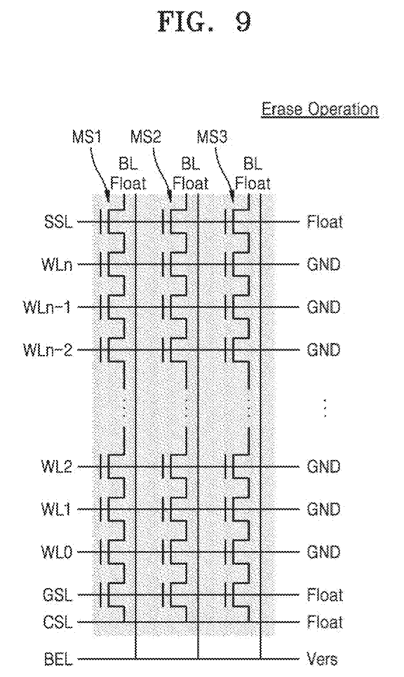

FIG. 9 is a circuit diagram schematically illustrating an erase operation of a memory device, according to one or more embodiments.

Referring to FIG. 9, a program operation may be performed in units of blocks for a plurality of memory cells. In the erase operation, the string selection line SSL may be located, the ground selection line GSL may be floated, and the common source line CSL may be floated. An erase voltage Vers may be applied to the back-side electrode line BEL. The erase voltage Vers may be a positive voltage and may range, for example, from 1 V to 10 V. The ground voltage GND may be applied to the word lines WL0, WL1, WL2, ..., WLn-2, WLn-1, and WLn, and the bit line BL may be floated.

In one or more embodiments, in the erase operation, the erase voltage Vers, which is a positive voltage, may be applied to the channel layer through the back-side electrode line BEL, and thus, a positive potential may be supplied to all of the memory strings MS1, MS2, and MS3 and a relatively large amount of holes may be provided. Due to the application of the erase voltage Vers, electrons may be tunneled at a relatively high speed from the charge storage film 144 (see, e.g., FIG. 6) into the channel layer 130 (see, e.g., FIG. 6). Accordingly, the erase operation may be performed rapidly and/or completely in all memory cells of the memory strings MS1, MS2, and MS3.

In general, a bonding-type memory device has a structure in which an end of a channel layer is connected to a common source line, instead of a substrate, and an erase operation of a memory cell is performed when an erase voltage is applied to the common source line and gate induced drain leakage (GIDL) current flows in the channel layer. However, when the channel layer includes an oxide semiconductor material, because the channel layer has a relatively large band gap energy, the number of hole carriers for transferring a positive potential into a memory string is not sufficiently large. Accordingly, the reliability of the GIDL-type erase operation in the memory device including the channel layer formed of the oxide semiconductor material is may not be ideal.

However, according to one or more embodiments, the erase voltage Vers, which is a positive voltage, may be applied to the channel layers of all of the memory strings MS1, MS2, and MS3 through the back-side electrode line BEL disposed adjacent to the channel layers (or through the back-side electrode line BEL directly connected to the channel layers with a conductive interfacial layer therebetween), and a positive potential may be rapidly supplied to all of the memory strings MS1, MS2, and MS3. Accordingly, the erase operation may be performed rapidly and/or completely in the memory cells of all of the memory strings MS1, MS2, and MS3, and the reliability of the erase operation of the memory device may be improved.

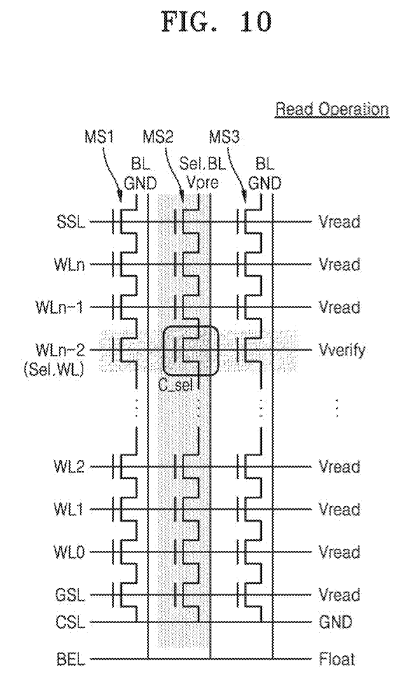

FIG. 10 is a circuit diagram schematically illustrating a read operation of a memory device, according to one or more embodiments.

Referring to FIG. 10, a read operation may be performed in units of pages for a plurality of memory cells. In the read operation, a read voltage Vread may be applied to the string selection line SSL, the read voltage Vread may be applied to the ground selection line GSL, the ground voltage GND may be applied to the common source line CSL, and the back-side electrode line BEL may be floated. The read voltage Vread may be applied to the unselected word lines WL0, WL1, WL2, ... WLn-1, and WLn, and a read level voltage Vverify may be applied to the selected word line WLn-2.

The ground voltage GND may be applied to the bit lines BL (e.g., unselected bit lines) of the first and third memory strings MS1 and MS3, and a precharge voltage Vpre may be applied to the bit line (e.g., the selected bit line Sel.BL) of the second memory string MS2. Next, during a read evaluation time, a voltage of the selected bit line Sel.BL may be changed according to a program state of the selected memory cell C_sel, and data of the memory cell C_sel (e.g., a program state or an erase state of the memory cell C_sel) disposed at an intersection between the selected word line WLn-2 and the selected bit line Sel.BL may be determined by sensing a voltage of the selected bit line Sel. BL.

The memory device 100 according to one or more embodiments described with reference to FIGS. 1 to 7 may operate according to the driving method described with reference to FIGS. 8 to 10. Accordingly, in the erase operation, the erase voltage Vers, which is a positive voltage, may be applied through the back-side electrode layer 132, the ground selection line GSL and the common source line CSL may be floated, and the bit line BL may be floated. Accordingly, a positive potential may be supplied to the entire memory string MS through the back-side electrode layer 132, and a relatively large amount of holes may be provided. Accordingly, because the erase operation may be performed rapidly and/or completely by using a body erase method in the entire area of the channel layer 130, the reliability of the erase operation may be improved.

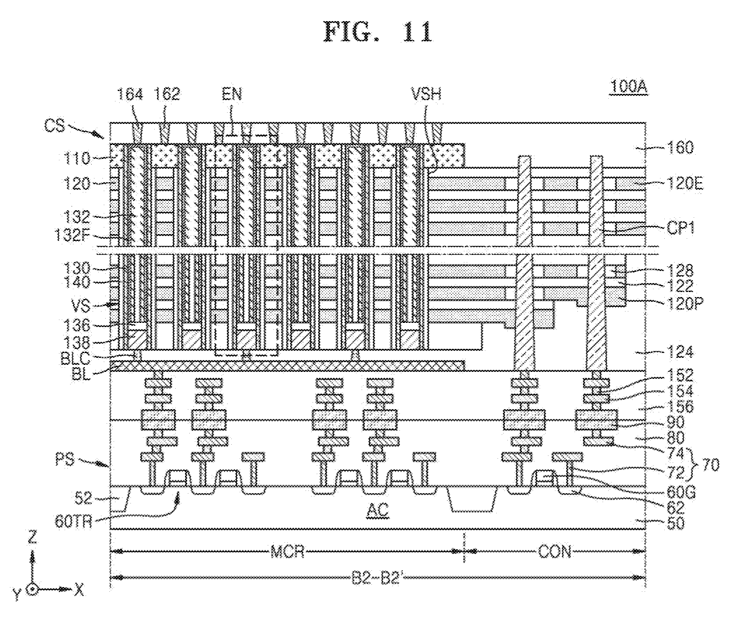

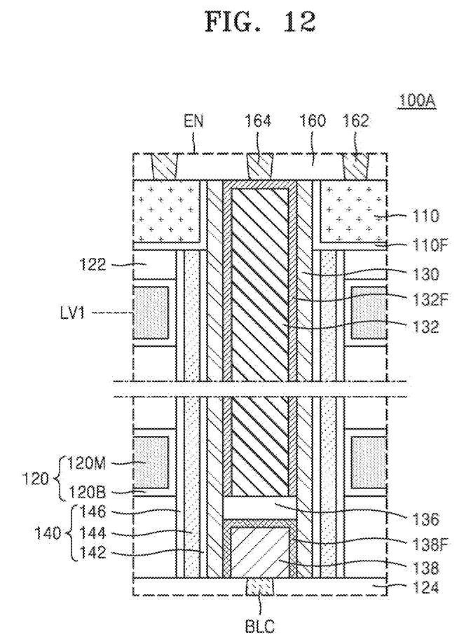

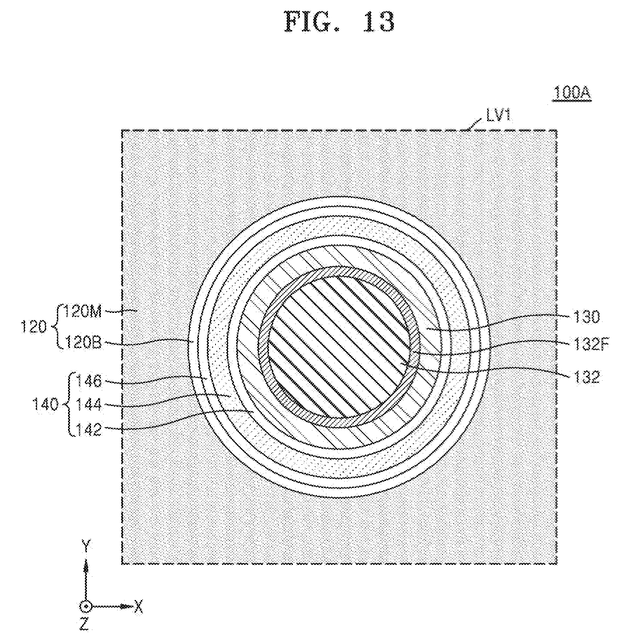

FIG. 11 is a cross-sectional view illustrating a memory device 100A, according to one or more embodiments. FIG. 12 is an enlarged view illustrating the portion EN of FIG. 11. FIG. 13 is a plan view at the first vertical level LV1 of FIG. 12.

Referring to FIGS. 11 to 13, the vertical structure VS may not include the buried insulating pillar 134 (see, e.g., FIG. 6). The buried insulating pillar 134 in the vertical structure VS may be omitted, and the back-side electrode layer 132 may have a pillar shape extending in the vertical direction Z in the vertical opening VSH. The back-side electrode layer 132 may have a circular horizontal cross-section.

A top surface of the spacer insulating layer 136 may contact an entire bottom surface of the back-side electrode layer 132, and the spacer insulating layer 136 may be disposed between the bottom surface of the back-side electrode layer 132 and a top surface of the bit line pad 138 to electrically insulate the back-side electrode layer 132 from the bit line pad 138.

According to one or more embodiments, as the back-side electrode layer 132 is disposed adjacent to the channel layer 130, an erase voltage may be applied through the back-side electrode layer 132, and a speed of an erase operation of the memory device 100A may be improved and the reliability of the erase operation may be improved.

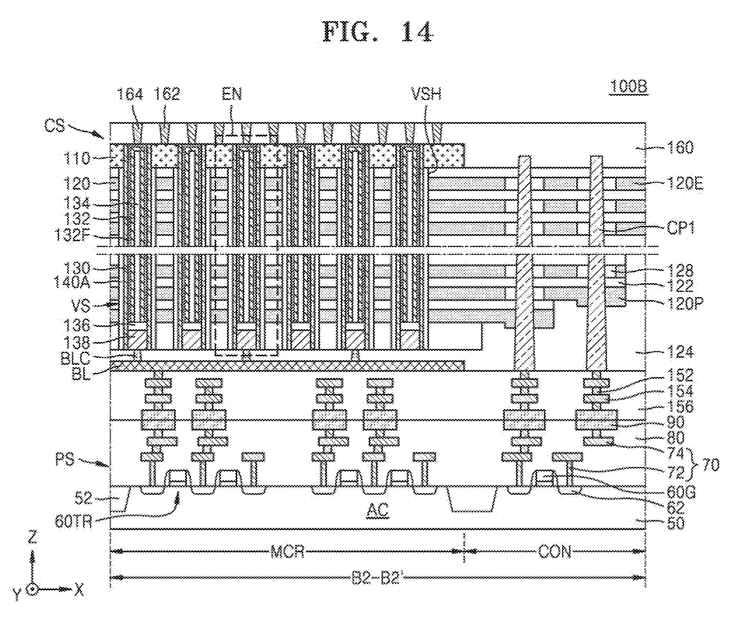

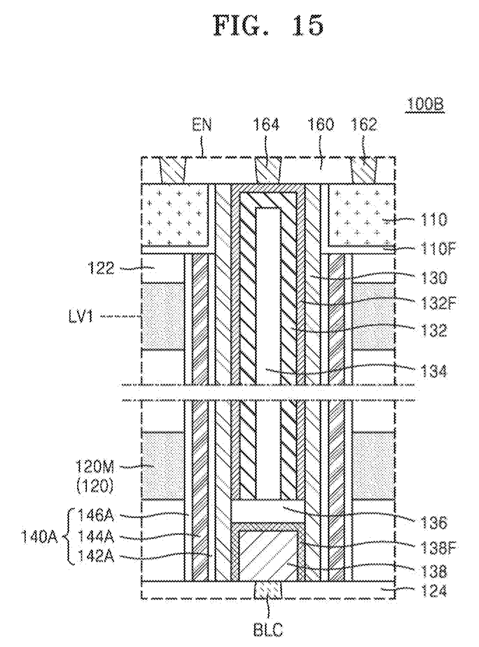

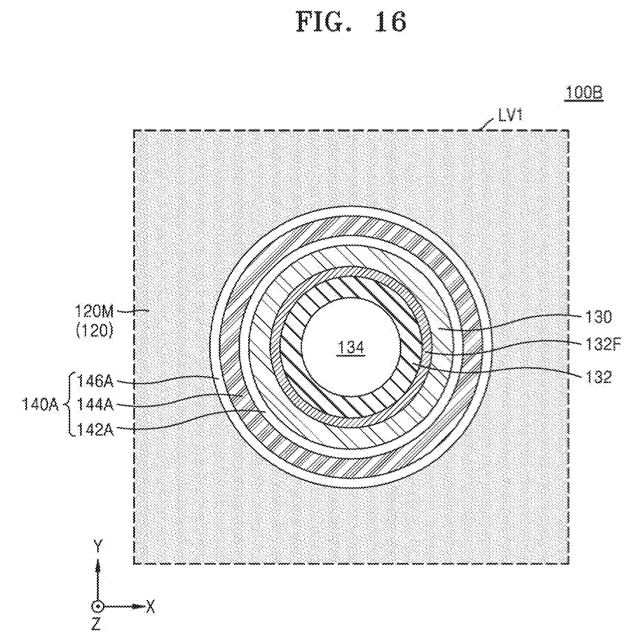

FIG. 14 is a cross-sectional view illustrating a memory device 100B, according to one or more embodiments. FIG. 15 is an enlarged view illustrating the portion EN of FIG. 14. FIG. 16 is a plan view at the first vertical level LV1 of FIG. 15.

Referring to FIGS. 14 to 16, a storage structure 140A disposed on an outer wall of the channel layer 130 may constitute a memory element of a nonvolatile memory device including a ferroelectric material.

In one or more embodiments, the storage structure 140A may include a first insulating layer 142A, a ferroelectric material layer 144A, and a second insulating layer 146A sequentially disposed on the outer wall of the channel layer 130. The ferroelectric material layer 144A may include a metal oxide having ferroelectric material characteristics. The ferroelectric material layer 144A may include a ferroelectric material capable of storing data by hysteresis behavior due to a voltage applied to the ferroelectric material layer 144A. In one or more embodiments, the ferroelectric material layer 144A may include at least one of hafnium oxide, zirconium oxide, or hafnium zirconium oxide. The first insulating layer 142A and the second insulating layer 146A may each include silicon oxide, silicon oxynitride, or silicon nitride.

According to one or more embodiments, as the back-side electrode layer 132 is disposed adjacent to the channel layer 130, an erase voltage may be applied through the back-side electrode layer 132, and the speed and reliability of an erase operation of the memory device 100B may be improved.

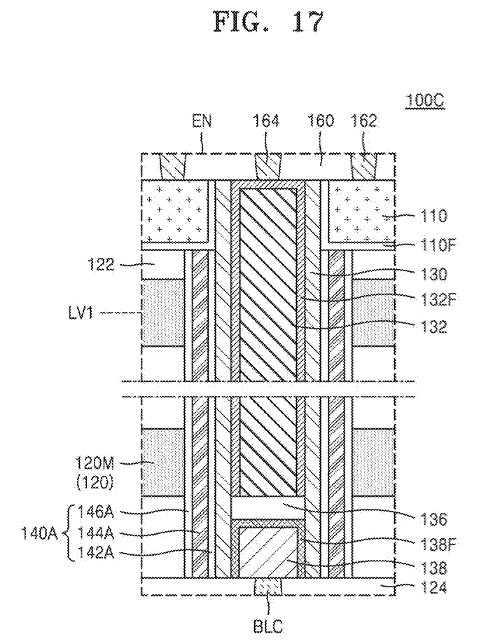

FIG. 17 is a cross-sectional view illustrating a memory device 100C, according to one or more embodiments.

Referring to FIG. 17, the memory device 100C may have similar technical features to the memory device 100B described with reference to FIGS. 14 to 16 except that the buried insulating pillar 134 (see, e.g., FIG. 15) is omitted. In one or more embodiments, the back-side electrode layer 132 may have a pillar shape extending in the vertical direction Z in the vertical opening VSH. The back-side electrode layer 132 may have a circular horizontal cross-section.

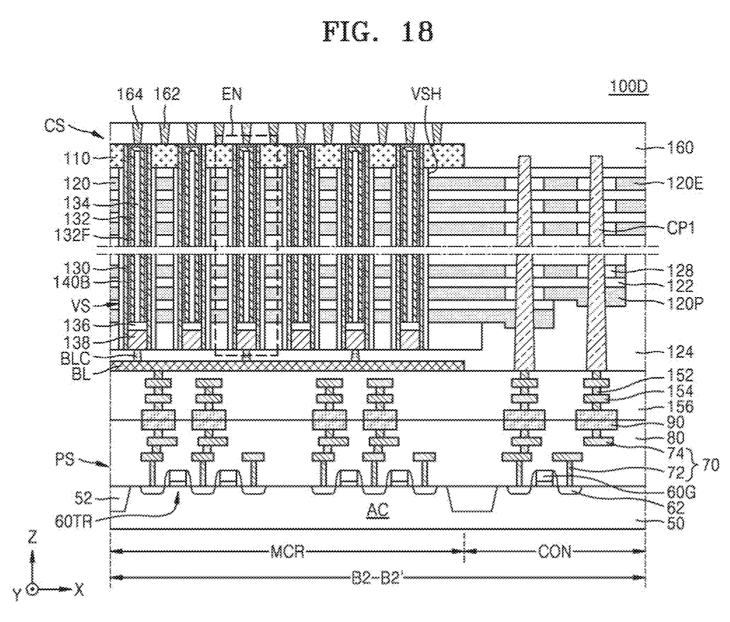

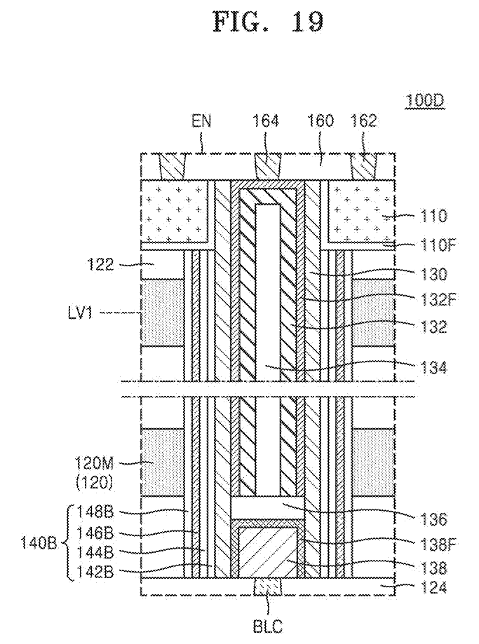

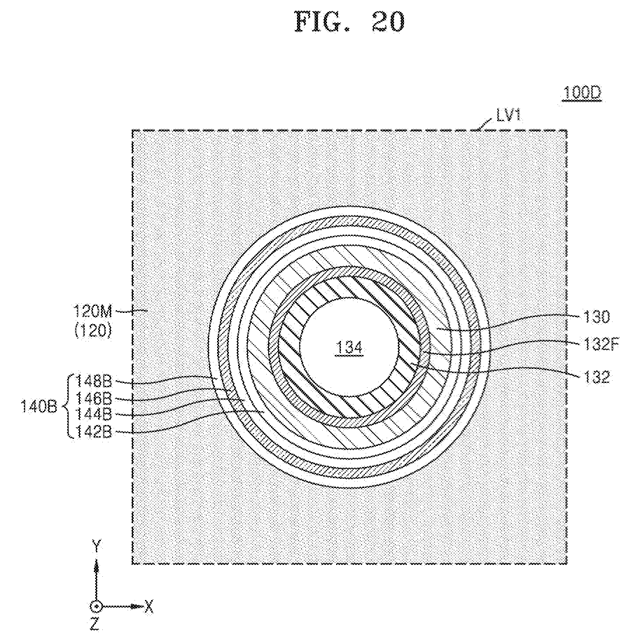

FIG. 18 is a cross-sectional view illustrating a memory device 100D, according to one or more embodiments. FIG. 19 is an enlarged view illustrating the portion EN of FIG. 18. FIG. 20 is a plan view at the first vertical level LV1 of FIG. 19.

Referring to FIGS. 18 to 20, a storage structure 140B disposed on an outer wall of the channel layer 130 may constitute a memory element of a nonvolatile memory device including an electrochemical cell.

In one or more embodiments, the storage structure 140B may include a resistive switching layer 142B, a barrier layer 144B, an electrolyte layer 146B, and a reservoir layer 148B sequentially disposed on the outer wall of the channel layer 130. The storage structure 140B may include a material capable of allowing oxygen ions or oxygen vacancies to diffuse or move due to an electric field applied to the storage structure 140B. In one or more embodiments, the storage structure 140B may include an electrochemical cell based on a metal oxide. The electrochemical cell based on the metal oxide may be driven by using the principle that oxygen ions or oxygen vacancies included in the metal oxide reversibly move due to the influence of an electric field formed in the metal oxide.

In one or more embodiments, the resistive switching layer 142B may include tungsten oxide. In one or more embodiments, the barrier layer 144B may include a metal oxide. In one or more embodiments, the electrolyte layer 146B may include at least one of hafnium oxide, zirconium oxide, yttrium zirconium oxide (or yttria-stabilized zirconia), or tungsten oxide. In one or more embodiments, the reservoir layer 148B may include at least one of tungsten oxide, gadolinium oxide, molybdenum oxide, tantalum oxide, aluminum oxide, titanium oxide, hafnium oxide, or silicon oxide. However, materials of the resistive switching layer 142B, the barrier layer 144B, the electrolyte layer 146B, and the reservoir layer 148B are not limited thereto. In one or more embodiments, the barrier layer 144B may be omitted.

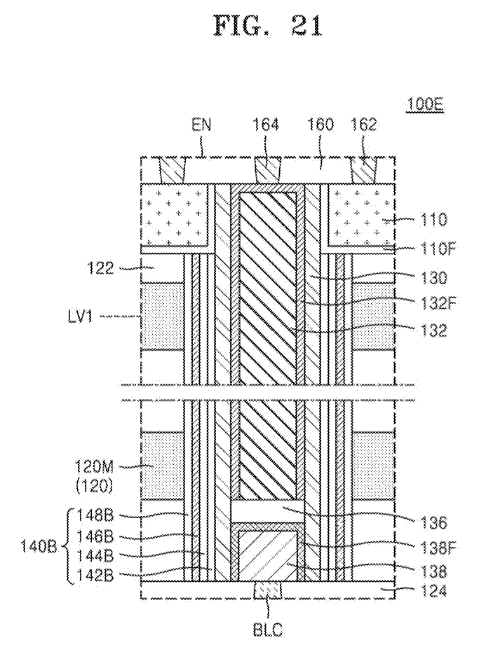

FIG. 21 is a cross-sectional view illustrating a memory device 100E, according to one or more embodiments.

Referring to FIG. 21, the memory device 100E may have similar technical features to the memory device 100C described with reference to FIGS. 18 to 20 except that the buried insulating pillar 134 (see, e.g., FIG. 20) is omitted. In one or more embodiments, the back-side electrode layer 132 may have a pillar shape extending in the vertical direction Z in the vertical opening VSH. The back-side electrode layer 132 may have a circular horizontal cross-section.

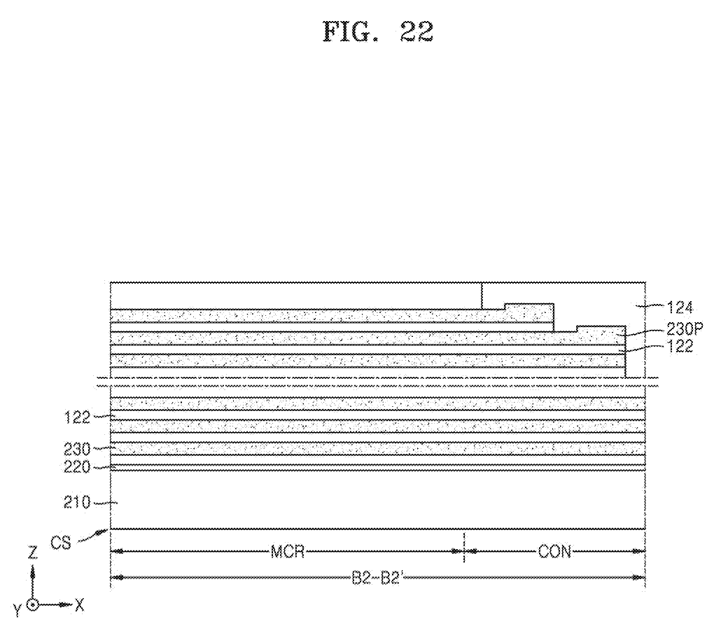

FIGS. 22, 23A, 23B, 24A, 24B, 25A, 25B, 26A, 26B, 27A, 27B, 28 to 31, 32A, 32B and 33 are cross-sectional views illustrating a method of manufacturing the memory device 100, according to one or more embodiments.

Referring to FIG. 22, an etch stop layer 220 may be formed on a cell substrate 210. In one or more embodiments, the cell substrate 210 may include at least one of silicon (Si), germanium (Ge), silicon germanium (SiGe), gallium arsenide (GaAs), indium gallium arsenide (InGaAs), aluminum gallium arsenide (AlGaAs), or a mixture thereof. The etch stop layer 220 may be formed by using a single layer structure including silicon oxide or a double layer structure including silicon oxide and polysilicon.

Next, in the cell array area MCR and the connection area CON, sacrificial gate electrodes 230 and the mold insulating layers 122 may be alternately formed. Next, in the connection area CON, sacrificial pad portions 230P having a stepped shape and connected to the sacrificial gate electrodes 230 may be formed. Next, the stack cover insulating layer 124 covering the sacrificial gate electrodes 230 and the sacrificial pad portions 230P may be formed.

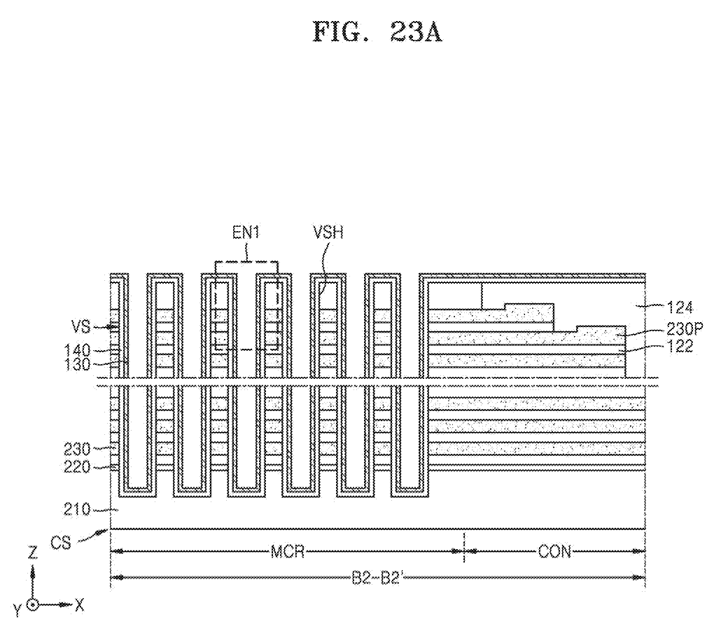

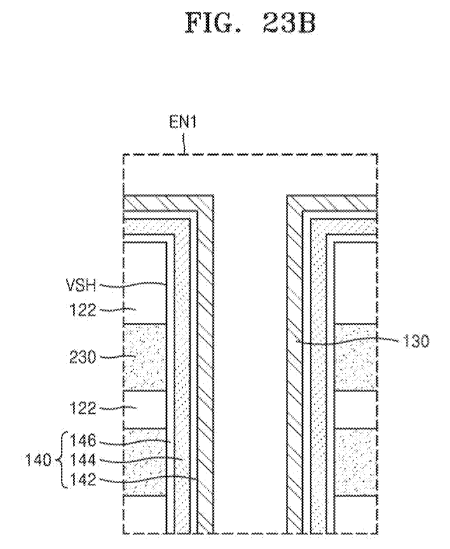

Referring to FIGS. 23A and 23B, in the cell array area MCR, the vertical opening VSH passing through the sacrificial gate electrodes 230 and the mold insulating layers 122 may be formed. The vertical opening VSH may pass through the etch stop layer 220 and may extend in the vertical direction Z, and a top surface of the cell substrate 210 may be exposed in a bottom portion of the vertical opening VSH.

Next, the storage structure 140 and the channel layer 130 may be conformally formed in the vertical opening VSH. Portions of the storage structure 140 and the channel layer 130 may also be disposed on a top surface of an uppermost mold insulating layer 122.

In one or more embodiments, the storage structure 140 may include the tunneling insulating film 142, the charge storage film 144, and the blocking dielectric film 146. In one or more embodiments, the blocking dielectric film 146, the charge storage film 144, and the tunneling insulating film 142 may be sequentially formed on an inner wall of the vertical opening VSH. Next, the channel layer 130 may be formed on the tunneling insulating film 142.

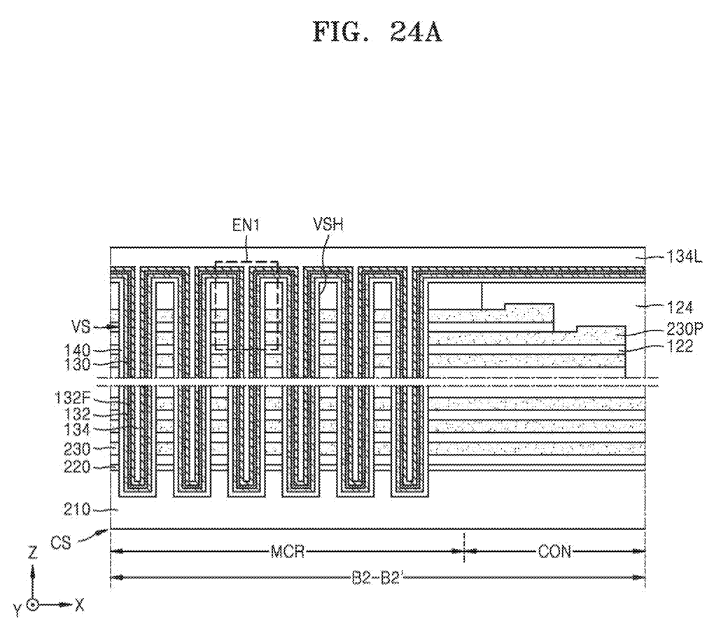

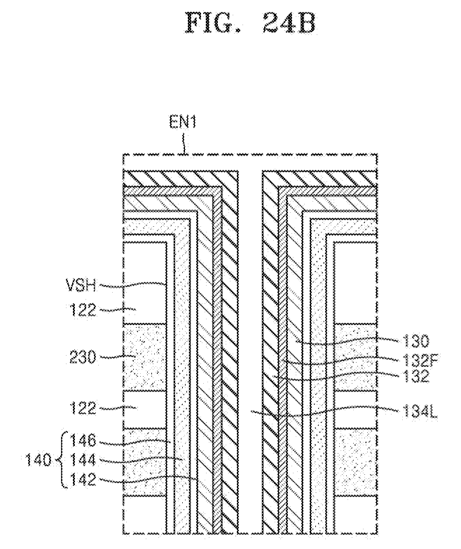

Referring to FIGS. 24A and 24B, the conductive interfacial layer 132F, the back-side electrode layer 132, and a buried insulating layer 134L may be formed in the vertical opening VSH. The conductive interfacial layer 132F and the back-side electrode layer 132 may be conformally and sequentially formed on an inner wall of the channel layer 130 in the vertical opening VSH, and the buried insulating layer 134L may fill the inside of the vertical opening VSH and may extend onto top surfaces of the uppermost mold insulating layer 122 and the stack cover insulating layer 124.

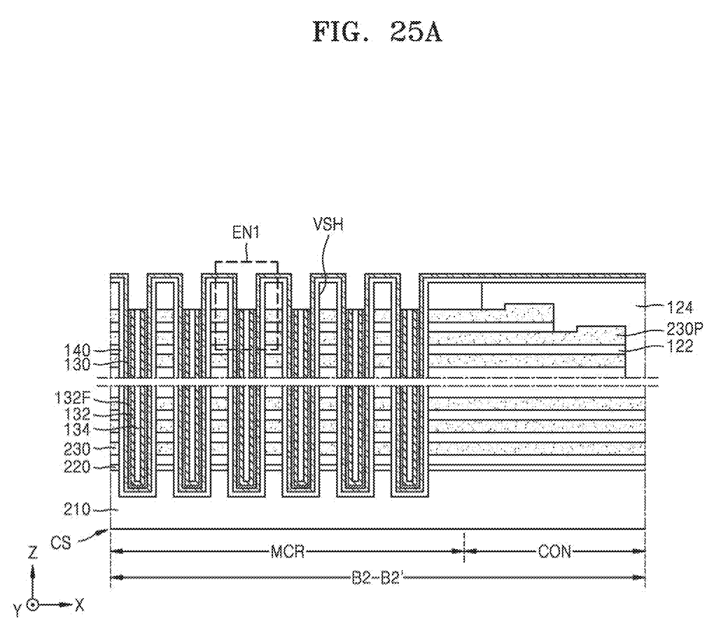

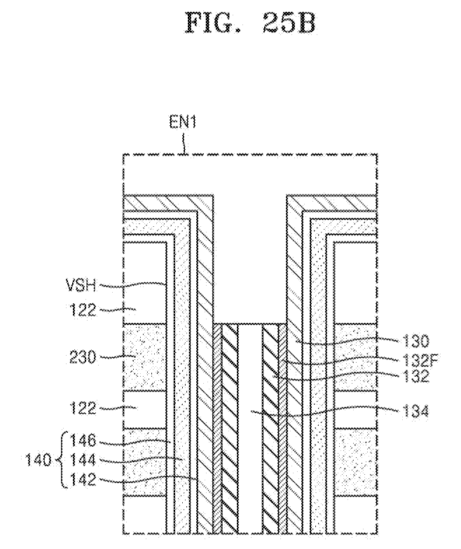

Referring to FIGS. 25A and 25B, upper portions of the buried insulating layer 134L, the back-side electrode layer 132, and the conductive interfacial layer 132F may be removed to lower levels of top surfaces of the buried insulating layer 134L, the back-side electrode layer 132, and the conductive interfacial layer 132F so that the top surfaces of the buried insulating layer 134L, the back-side electrode layer 132, and the conductive interfacial layer 132F are disposed inside the vertical opening VSH.

In one or more embodiments, a process of removing the upper portions of the buried insulating layer 134L, the back-side electrode layer 132, and the conductive interfacial layer 132F may include a wet etching process, a dry etching process, or an etch-back process.

A portion of the buried insulating layer 134L remaining in the vertical opening VSH after the removing process is referred to as the buried insulating pillar 134. In one or more embodiments, the top surface of the back-side electrode layer 132 may be disposed at a vertical level higher than or equal to that of a top surface of the uppermost sacrificial gate electrode 230. Also, the top surface of the buried insulating pillar 134 may be disposed at a vertical level higher than or equal to that of the top surface of the uppermost sacrificial gate electrode 230.

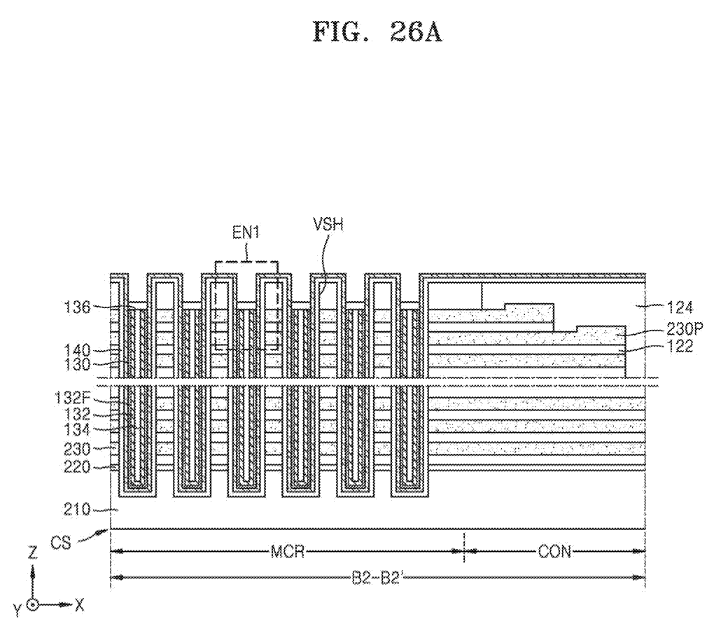

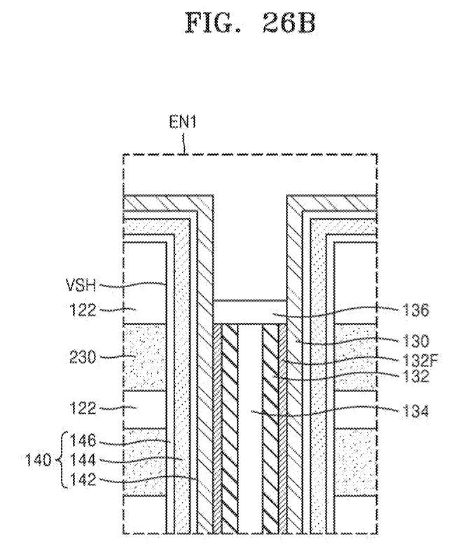

Referring to FIGS. 26A and 26B, the spacer insulating layer 136 may be formed in an upper portion of the vertical opening VSH. The spacer insulating layer 136 may be disposed on an inner wall of the channel layer 130, and may cover the top surfaces of the back-side electrode layer 132, the conductive interfacial layer 132F, and the buried insulating pillar 134.

In one or more embodiments, the spacer insulating layer 136 filling the upper portion of the vertical opening VSH may be formed, and an etch-back process may be performed on an upper portion of the spacer insulating layer 136 to lower a level of a top surface of the spacer insulating layer 136 so that the top surface of the spacer insulating layer 136 is disposed at a lower level than a top surface of the vertical opening VSH. Accordingly, a part of the upper portion of the vertical opening VSH may remain unfilled by the spacer insulating layer 136.

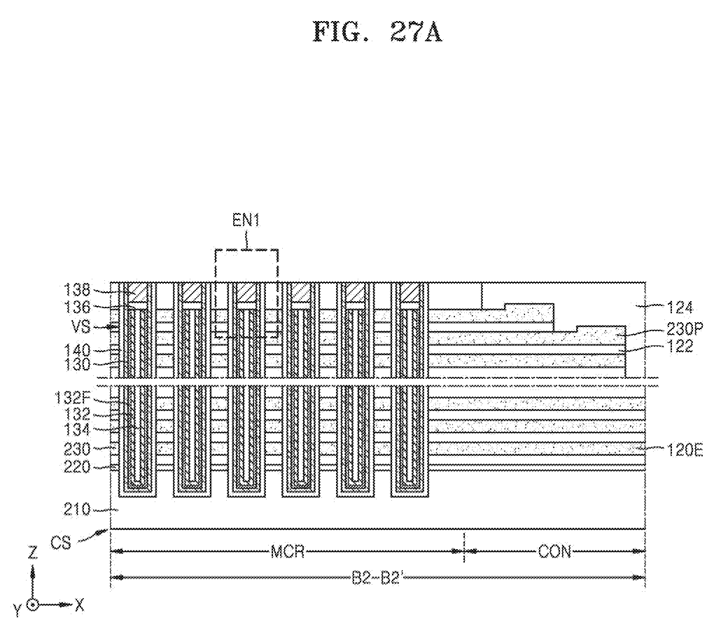

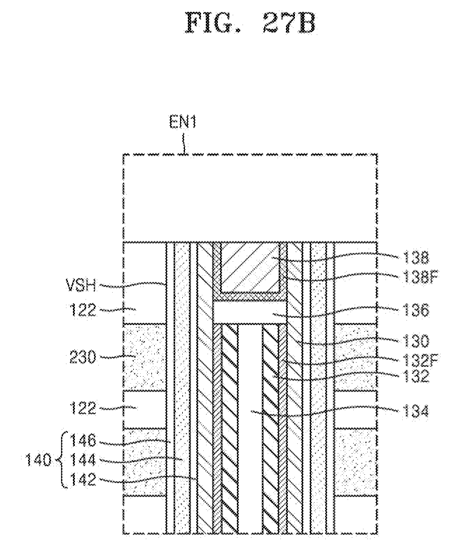

Referring to FIGS. 27A and 27B, a pad interfacial layer 138F may be formed on an inner wall of the upper portion of the vertical opening VSH, and the bit line pad 138 filling the inside of the upper portion of the vertical opening VSH may be sequentially formed on the pad interfacial layer 138F.

In one or more embodiments, a chemical mechanical polishing (CMP) process may be performed to form the bit line pad 138, and a portion of the channel layer 130 disposed on a top surface of the uppermost mold insulating layer 122 may also be removed during the CMP process and/or by using an additional CMP process after the CMP process. Accordingly, the channel layer 130 may have a top surface disposed at the same plane as the top surface of the uppermost mold insulating layer 122.

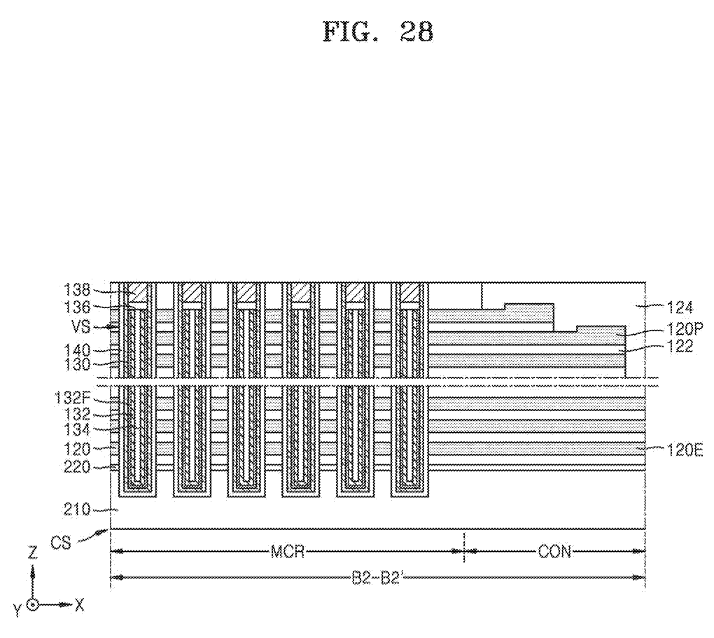

Referring to FIG. 28, the stack separation opening WLH (see, e.g., FIG. 4) passing through the mold insulating layer 122 and the sacrificial gate electrodes 230 may be formed, and the sacrificial gate electrodes 230 may be replaced with the gate electrodes 120 through the stack separation opening WLH. In one or more embodiments, the sacrificial gate electrodes 230 may be removed by using a wet etching process through the stack separation opening WLH, and the gate electrodes 120 may be formed in a space where the sacrificial gate electrodes 230 are removed. Also, in the connection area CON, the sacrificial pad portions 230P may be removed, and the gate pad portions 120P may be formed in a space where the sacrificial pad portions 230P are removed.

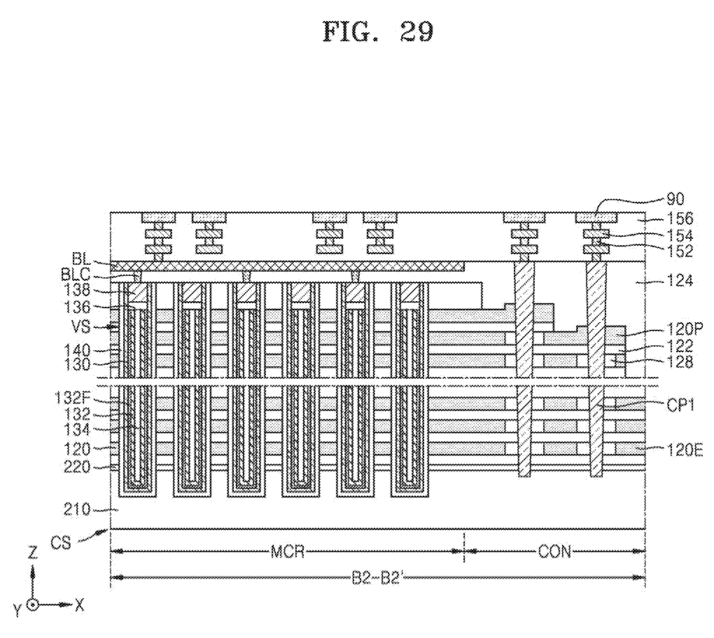

Referring to FIG. 29, in the cell array area MCR, the bit line plug BLC and the bit line BL may be formed. Next, in the connection area CON, the cell plug CP1 passing through the gate pad portions 120P and extending in the vertical direction Z may be formed.

Next, the connection via 152 and the connection wiring layer 154 electrically connected to the bit line BL and the cell plug CP1, and the interlayer insulating film 156 may be formed. A connection pad 90 may be formed on a top surface of the interlayer insulating film 156.

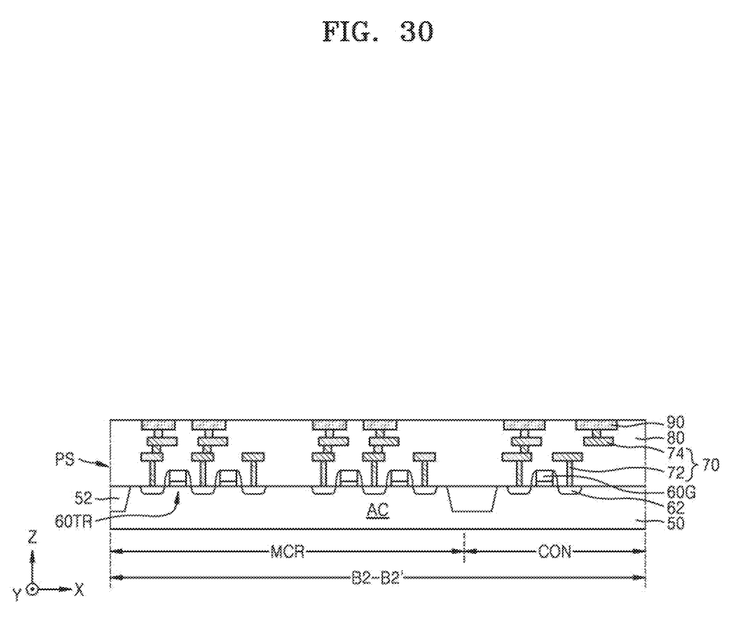

Referring to FIG. 30, the peripheral circuit structure PS may be prepared. The peripheral circuit structure PS may include the peripheral circuit transistor 60TR and the peripheral circuit wiring structure 70 disposed on the substrate 50. The active area AC may be defined by the device isolation film 52 in the substrate 50, and a plurality of peripheral circuit transistors 60TR may be formed on the active area AC. The plurality of peripheral circuit transistors 60TR may include the peripheral circuit gate 60G, and the source/drain regions 62 disposed on a portion of the substrate 50 on both sides of the peripheral circuit gate 60G.

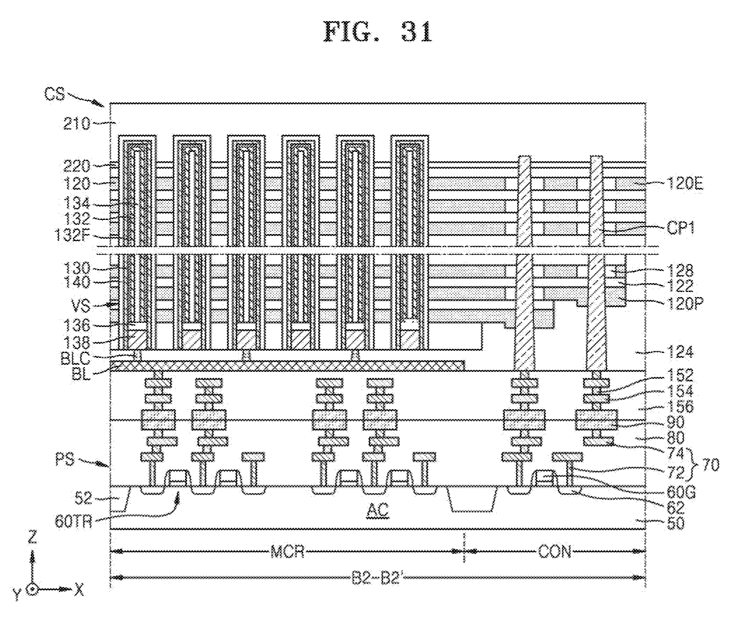

Referring to FIG. 31, the peripheral circuit structure PS may be attached to the cell array structure CS. The peripheral circuit structure PS and the cell array structure CS may be attached by using a metal-oxide hybrid bonding method through the connection pad 90 and the interlayer insulating films 80 and 156, but the disclosure is not limited thereto.

Next, a structure in which the peripheral circuit structure PS and the cell array structure CS are attached may be turned upside down so that the cell substrate 210 faces upward.

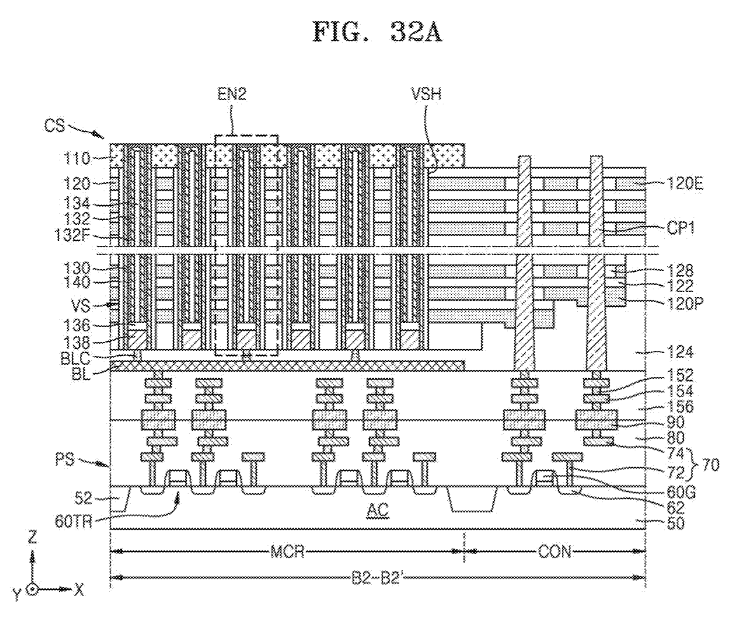

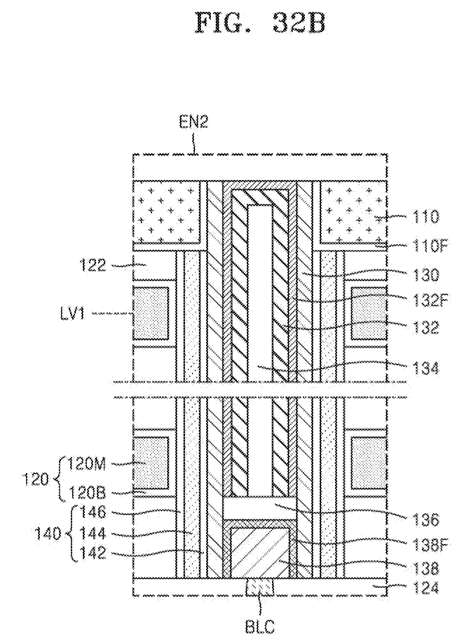

Referring to FIGS. 32A and 32B, the cell substrate 210 (see, e.g., FIG. 31) may be removed. The cell substrate 210 may be removed by using a grinding process and a subsequent etching process, and the etch stop layer 220 (see FIG. 31) may be exposed.

Next, the etch stop layer 220 may also be removed. As the etch stop layer 220 is removed, a top surface of the storage structure 140 may be exposed and may protrude above a top surface of the uppermost mold insulating layer 122.

Next, a portion of the storage structure 140 protruding above the top surface of the uppermost mold insulating layer 122 may be removed to expose a top surface and a side wall of the channel layer 130. In a process of removing the storage structure 140, the process of removing the storage structure 140 may be performed until a top surface of the etch stop layer 220 is exposed. In one or more embodiments, an upper portion of the storage structure 140 may be removed so that the storage structure 140 may be disposed at a lower level than the top surface of the channel layer 130 and portions of the top surface and the side wall of the channel layer 130 are exposed.

Next, the common source layer 110 may be formed in the cell array area MCR. The common source layer 110 may be formed of polysilicon. For example, the common source layer 110 may be formed of polysilicon doped with n-type impurities. The common source layer 110 may be conformally formed on the top surface of the uppermost mold insulating layer 122 and the exposed top surface of the channel layer 130.

In one or more embodiments, selectively, optionally, before the common source layer 110 is formed, the interfacial layer 110F may be conformally formed on the top surface of the uppermost mold insulating layer 122 and the exposed top surface of the channel layer 130.

Next, a planarization process may be performed on an upper portion of the common source layer 110 until the top surface of the channel layer 130 is exposed, and thus, a top surface of the common source layer 110 may be disposed at the same level as the top surface of the channel layer 130.

Next, a top surface of the conductive interfacial layer 132F may be exposed by removing a part of the exposed upper portion of the channel layer 130.

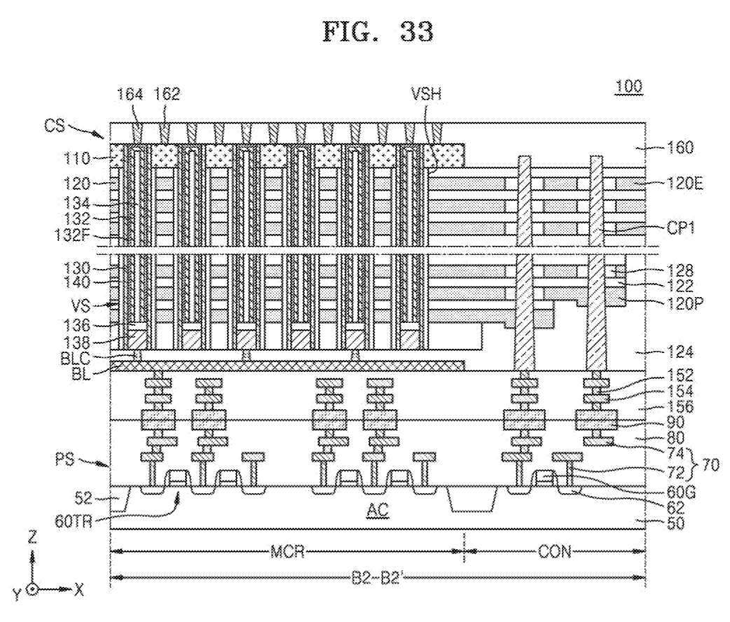

Referring to FIG. 33, the upper insulating layer 160 covering the top surfaces of the common source layer 110 and the conductive interfacial layer 132F in the cell array area MCR and covering a top surface of the cell plug CP1 in the connection area CON may be formed. A via hole passing through the upper insulating layer 160 may be formed and the first connection via 162 and the second connection via 164 may be formed by using a conductive material in the via hole.

The memory device 100 may be completed by performing the above process.

According to one or more embodiments, a back-side electrode layer may be disposed on a side wall of a channel layer, and an erase voltage may be applied to the back-side electrode layer in an erase operation of a memory device. Accordingly, because the erase operation may be performed on a memory cell in a similar manner to a body erase effect, the reliability related to the erase operation of the memory cell may be improved.

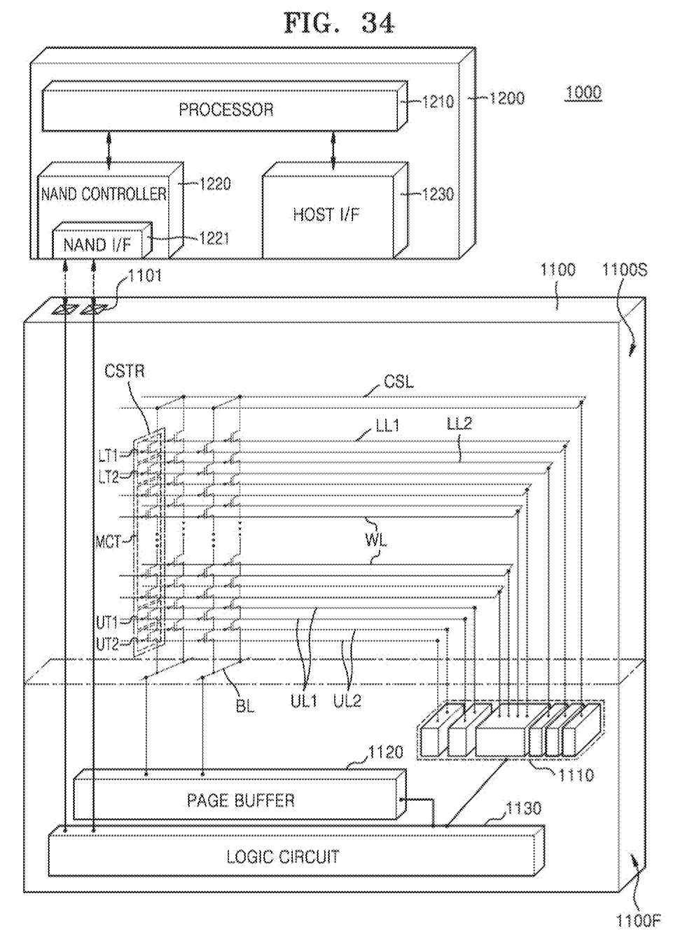

FIG. 34 is a view schematically illustrating a data storage system 1000 including a memory device, according to one or more embodiments.

Referring to FIG. 34, the data storage system 1000 may include one or more memory devices 1100 and a memory controller 1200 electrically connected to the memory devices 1100. The data storage system 1000 may be, for example, a solid-state drive (SSD) device, a universal serial bus (USB), a computing system, a medical device, or a communication device including at least one memory device 1100.

The memory device 1100 may be a nonvolatile memory device. For example, the memory device 1100 may be a NAND flash memory device including one of the memory devices 10, 100, 100A, 100B, 100C, 100D, and 100E described with reference to FIGS. 1 to 21. The memory device 1100 may include a first structure 1100F and a second structure 1100S on the first structure 1100F. The first structure 1100F may be a peripheral circuit structure including a row decoder 1110, a page buffer 1120, and a logic circuit 1130.

The second structure 1100S may be a memory cell structure including the bit line BL, the common source line CSL, the plurality of word lines WL, first and second string selection lines UL1 and UL2, first and second ground selection lines LL1 and LL2, and a plurality of memory cell strings CSTR located between the bit line BL and the common source line CSL.

In the second structure 1100S, each of the plurality of memory cell strings CSTR may include ground selection transistors LT1 and LT2 adjacent to the common source line CSL, string selection transistors UT1 and UT2 adjacent to the bit line BL, and a plurality of memory cell transistors MCT located between the ground selection transistors LT1 and LT2 and the string selection transistors UT1 and UT2. The number of ground selection transistors LT1 and LT2 and the number of string selection transistors UT1 and UT2 may be changed in various ways according to one or more embodiments.

In one or more embodiments, the plurality of ground selection lines LL1 and LL2 may be respectively connected to gate electrodes of the ground selection transistors LT1 and LT2. The word line WL may be connected to a gate electrode of the memory cell transistor MCT. The plurality of string selection lines UL1 and UL2 may be respectively connected to gate electrodes of the string selection transistors UT1 and UT2.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The memory device 1100 may communicate with the memory controller 1200 through an input/output pad 1101 electrically connected to the logic circuit 1130. The input/output pad 1101 may be electrically connected to the logic circuit 1130.

The memory controller 1200 may include a processor 1210, a NAND controller 1220, and a host interface 1230. In one or more embodiments, the data storage system 1000 may include a plurality of memory devices 1100, and in this case, the memory controller 1200 may control the plurality of memory devices 1100.

The processor 1210 may control an overall operation of the data storage system 1000 including the memory controller 1200. The processor 1210 may operate according to certain firmware and may access the memory device 1100 by controlling the NAND controller 1220. The NAND controller 1220 may include a NAND interface 1221 communicating with the memory device 1100. Through the NAND interface 1221, a control command for controlling the memory device 1100, data to be written to the plurality of memory cell transistors MCT of the memory device 1100, and data to be read from the plurality of memory cell transistors MCT of the memory device 1100 may be transmitted. The host interface 1230 may provide a communication function between the data storage system 1000 and an external host. When a control command is received from the external host through the host interface 1230, the processor 1210 may control the memory device 1100 in response to the control command.

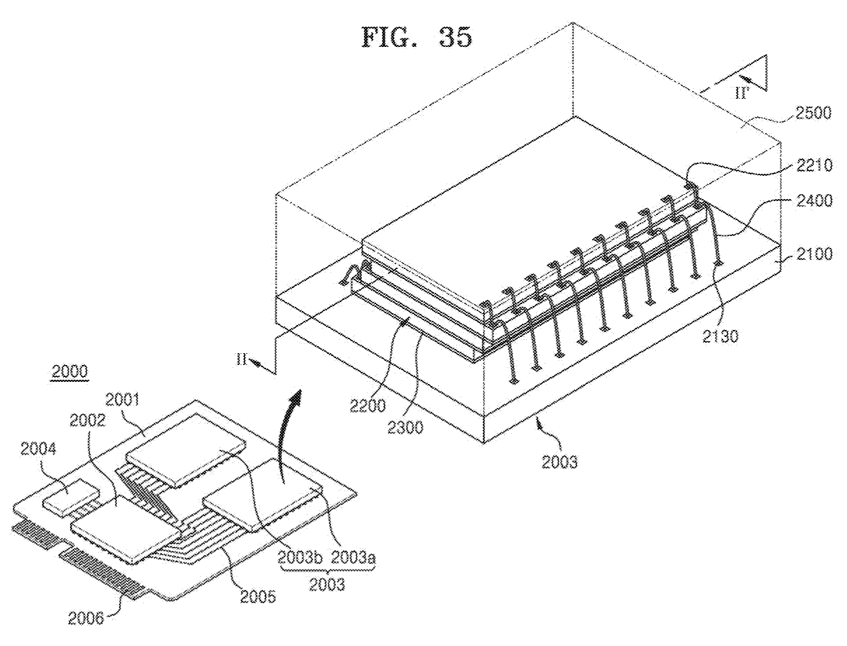

FIG. 35 is a perspective view schematically illustrating a data storage system 2000 including a memory device, according to one or more embodiments.

Referring to FIG. 35, the data storage system 2000 according to an embodiment may include a main substrate 2001, a memory controller 2002, one or more semiconductor packages 2003, and a dynamic random-access memory (DRAM) 2004 on the main substrate 2001. The semiconductor packages 2003 and the DRAM 2004 may be connected to the memory controller 2002 by a plurality of wiring patterns 2005 formed on the main substrate 2001.

The main substrate 2001 may include a connector 2006 including a plurality of pins coupled to an external host. The number and arrangement of pins in the connector 2006 may vary according to a communication interface between the data storage system 2000 and the external host. In one or more embodiments, the data storage system 2000 may communicate with the external host according to any one of interfaces such as universal serial bus (USB), peripheral component interconnect express (PCI-Express), serial advanced technology attachment (SATA), and M-Phy for universal flash storage (UFS). In one or more embodiments, the data storage system 2000 may operate with power supplied from the external host through the connector 2006. The data storage system 2000 may further include a power management integrated circuit (PMIC) that distributes power received from the external host to the memory controller 2002 and the semiconductor packages 2003.

The memory controller 2002 may write data to the semiconductor packages 2003, may read data from the semiconductor packages 2003, or may increase an operating speed of the data storage system 2000.

The DRAM 2004 may be a buffer memory for reducing a speed difference between the external host and the semiconductor packages 2003 that are data storage spaces. The DRAM 2004 included in the data storage system 2000 may operate as a cache memory and may provide a space for temporarily storing data during a control operation for the semiconductor packages 2003. When the DRAM 2004 is included in the data storage system 2000, the memory controller 2002 may further include a DRAM controller for controlling the DRAM 2004 in addition to a NAND controller for controlling the semiconductor packages 2003.

The semiconductor packages 2003 may include first and second semiconductor packages 2003a and 2003b which are spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, the plurality of semiconductor chips 2200 on the package substrate 2100, an adhesive layer 2300 located on a bottom surface of each of the plurality of semiconductor chips 2200, a connection structure 2400 configured to electrically connect the plurality of semiconductor chips 2200 to the package substrate 2100, and a molding layer 2500 located on the package substrate 2100 to cover the plurality of semiconductor chips 2200 and the connection structure 2400.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 34. Each of the plurality of semiconductor chips 2200 may include at least one of the memory devices 10, 100, 100A, 100B, 100C, 100D, and 100E described with reference to FIGS. 1 to 21.

In one or more embodiments, the connection structure 2400 may be a bonding wire configured to electrically connect the input/output pad 2210 to the package upper pad 2130. Accordingly, in the first and second semiconductor packages 2003a and 2003b, the plurality of semiconductor chips 2200 may be electrically connected to each other by using a bonding wire method and may be electrically connected to the package upper pad 2130 of the package substrate 2100. In one or more embodiments, in the first and second semiconductor packages 2003a and 2003b, the plurality of semiconductor chips 2200 may be electrically connected to each other by a connection structure including a through silicon via (TSV), instead of the connection structure 2400 using a bonding wire method.

In one or more embodiments, the memory controller 2002 and the plurality of semiconductor chips 2200 may be included in one package. In one or more embodiments, the memory controller 2002 and the plurality of semiconductor chips 2200 may be mounted on a separate interposer substrate different from the main substrate 2001, and the memory controller 2002 and the plurality of semiconductor chips 2200 may be connected to each other by a wiring formed on the interposer substrate.

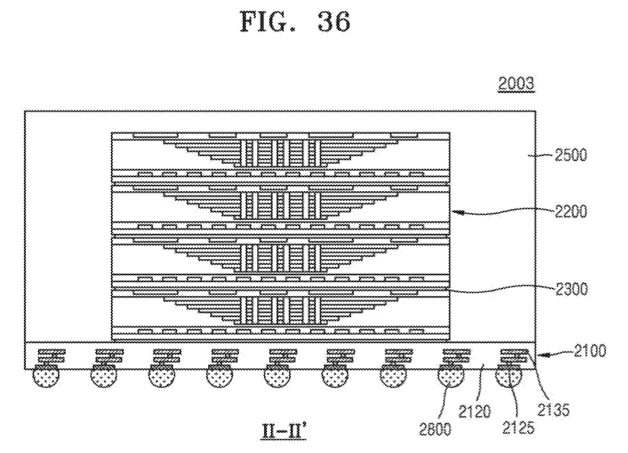

FIG. 36 is a cross-sectional view schematically illustrating the semiconductor packages 2003, according to one or more embodiments. FIG. 36 is a cross-sectional view taken along line II-II’ of FIG. 35.

Referring to FIG. 36, in the semiconductor package 2003, the package substrate 2100 may be a printed circuit board. The package substrate 2100 may include a package substrate body portion 2120, a plurality of package upper pads 2130 (see, e.g., FIG. 35) disposed on a top surface of the package substrate body portion 2120, a plurality of lower pads 2125 disposed on or exposed through a bottom surface of the package substrate body portion 2120, and a plurality of internal wirings 2135 configured to electrically connect the plurality of package upper pads 2130 (see, e.g., FIG. 35) to the plurality of lower pads 2125 inside the package substrate body portion 2120. As shown in FIG. 35, the plurality of package upper pads 2130 may be electrically connected to the plurality of connection structures 2400. As shown in FIG. 36, the plurality of lower pads 2125 may be connected to the plurality of wiring patterns 2005 on the main substrate 2001 of the data storage system 2000 of FIG. 35 through a plurality of conductive bumps 2800. Each of the plurality of semiconductor chips 2200 may include at least one of the memory devices 10, 100, 100A, 100B, 100C, 100D, and 100E described with reference to FIGS. 1 to 21.

At least one of the components, elements, modules, units, or the like (collectively "components" in this paragraph) represented by a block or an equivalent indication (collectively “block”) in the above embodiments including the drawings such as FIGS. 1 and 34, for example, row decoder, page buffer, data I/O circuit, control logic, controller, flip-flop, latch, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

As described above, one or more embodiments have been illustrated in the drawings and described in the specification. While these one or more embodiments have been described by using specific terms, the terms have merely been used to explain the disclosure and should not be construed as limiting the scope of the disclosure defined by the claims. Hence, it will be understood by one of ordinary skill in the art that various modifications and other equivalent embodiments may be made therefrom. Accordingly, the technical scope of the disclosure should be defined by the following claims.

While the disclosure has been particularly shown and described with reference to one or more embodiments thereof, it will be understood that various changes in form and details may be made therein without departing from the spirit and scope of the following claims.

What is claimed is:

1. A memory device comprising:
a peripheral circuit structure; and
a cell array structure on the peripheral circuit structure,
wherein the cell array structure comprises:
gate electrodes spaced apart in a vertical direction;
a channel layer passing through the gate electrodes, wherein the channel layer comprises an oxide semiconductor and is in a vertical opening extending in the vertical direction;
a back-side electrode layer extending in the vertical direction in the vertical opening, wherein the back-side electrode layer is on a side wall of the channel layer;
a conductive interfacial layer extending in the vertical direction in the vertical opening, wherein the conductive interfacial layer is between the side wall of the channel layer and the back-side electrode layer; and
a bit line pad on the side wall of the channel layer in the vertical opening and spaced apart from the back-side electrode layer in the vertical direction.

2. The memory device of claim 1, wherein the cell array structure further comprises:
a bit line connected to a first end of the channel layer; and
a common source line on at least a portion of an outer wall of a second end of the channel layer, wherein the second end is opposite to the first end.

3. The memory device of claim 2, wherein the cell array structure further comprises a pad interfacial layer between the side wall of the channel layer and the bit line pad.

4. The memory device of claim 2, wherein the common source line at least partially surrounds the outer wall of the second end of the channel layer, and
wherein the back-side electrode layer is on an inner wall of the second end of the channel layer.

5. The memory device of claim 2, wherein the cell array structure further comprises:
an upper insulating layer on a top surface of the common source line;
a first connection via passing through the upper insulating layer and connected to the top surface of the common source line; and
a second connection via passing through the upper insulating layer, wherein the second connection via is on a top surface of the back-side electrode layer.

6. The memory device of claim 1, wherein the cell array structure further comprises a spacer insulating layer on the side wall of the channel layer in the vertical opening, wherein the spacer insulating layer is between the back-side electrode layer and the bit line pad.

7. The memory device of claim 1, wherein the oxide semiconductor comprises at least one of indium gallium zinc oxide, indium aluminum zinc oxide, indium gallium oxide, indium zinc oxide, zinc oxide, zinc tin oxide, indium oxide, titanium oxide, tungsten oxide, or praseodymium chromium manganese oxide, and
wherein the back-side electrode layer comprises at least one of a metal, a metal nitride, a p-type oxide semiconductor, or p-type polysilicon.

8. The memory device of claim 1, wherein the back-side electrode layer comprises at least one of tungsten, molybdenum, niobium, nickel, cobalt, copper, palladium, platinum, ruthenium, iridium, gold, silver, chromium, rhodium, indium, tin, magnesium, zinc, beryllium, strontium, barium, titanium nitride, tantalum nitride, tungsten nitride, tin oxide, copper oxide, nickel oxide, or p-type polysilicon, and
wherein the conductive interfacial layer comprises at least one of molybdenum oxide, indium oxide, tungsten oxide, tin oxide, indium tin oxide, indium tungsten oxide, titanium nitride, tantalum nitride, or tungsten nitride.

9. The memory device of claim 1, wherein the back-side electrode layer has a top surface at a vertical level higher than a vertical level of an uppermost gate electrode among the gate electrodes, and has a bottom surface at a vertical level lower than or equal to a vertical level of a lowermost gate electrode among the gate electrodes.

10. The memory device of claim 1, wherein the back-side electrode layer has a cylindrical shape extending in the vertical direction in the vertical opening, and
wherein the cell array structure further comprises a buried insulating pillar on an inner wall of the back-side electrode layer.

11. The memory device of claim 1, wherein the back-side electrode layer has a pillar shape filling the vertical opening.

12. The memory device of claim 1, further comprising a storage structure in the vertical opening,
wherein the storage structure is between the gate electrodes and the channel layer, and
wherein the storage structure comprises a tunneling insulating film, a charge storage film, and a blocking dielectric film sequentially disposed on an outer wall of the channel layer.

13. The memory device of claim 1, further comprising a storage structure in the vertical opening,
wherein the storage structure is between the gate electrodes and the channel layer, and
wherein the storage structure comprises a ferroelectric material layer extending in the vertical direction in the vertical opening.

14. The memory device of claim 1, further comprising a storage structure in the vertical opening,
wherein the storage structure is between the gate electrodes and the channel layer,
wherein the storage structure comprises a resistive switching layer, a barrier layer, an electrolyte layer, and a reservoir layer sequentially disposed on an outer wall of the channel layer,
wherein the electrolyte layer comprises at least one of hafnium oxide, zirconium oxide, yttrium zirconium oxide, or tungsten oxide, and
wherein the reservoir layer comprises at least one of tungsten oxide, gadolinium oxide, molybdenum oxide, tantalum oxide, aluminum oxide, titanium oxide, hafnium oxide, or silicon oxide.

15. A memory device comprising:
a peripheral circuit structure; and
a cell array structure on the peripheral circuit structure,
wherein the cell array structure comprises:
gate electrodes spaced apart in a vertical direction;
a storage structure passing through the gate electrodes, wherein the storage structure comprises a charge storage film and is in a vertical opening extending in the vertical direction;
a channel layer on an inner wall of the storage structure in the vertical opening, the channel layer comprising an oxide semiconductor;
a conductive interfacial layer on an inner wall of the channel layer in the vertical opening;
a back-side electrode layer on an inner wall of the conductive interfacial layer in the vertical opening; and
a bit line pad connected to a bottom portion of the channel layer in the vertical opening and spaced apart from the back-side electrode layer in the vertical direction.

16. The memory device of claim 15, wherein the cell array structure further comprises:
a bit line connected to the bit line pad;
a common source line on an outer wall of an upper portion of the channel layer;
an upper insulating layer on a top surface of the common source line;
a first connection via passing through the upper insulating layer and connected to the top surface of the common source line; and
a second connection via passing through the upper insulating layer, wherein the second connection via is on a top surface of the back-side electrode layer.

17. The memory device of claim 15, wherein the back-side electrode layer has a top surface at a vertical level higher than a vertical level of an uppermost gate electrode among the gate electrodes, and has a bottom surface at a vertical level lower than or equal to a vertical level of a lowermost gate electrode among the gate electrodes.

18. The memory device of claim 15, wherein the cell array structure further comprises:
a pad interfacial layer between the inner wall of the channel layer and the bit line pad in the vertical opening; and
a spacer insulating layer on the inner wall of the channel layer in the vertical opening, wherein the spacer insulating layer is between the back-side electrode layer and the bit line pad.

19. A memory device comprising:
a peripheral circuit structure; and
a cell array structure on the peripheral circuit structure,
wherein the cell array structure comprises:
gate electrodes spaced apart in a vertical direction;
a storage structure passing through the gate electrodes, wherein the storage structure comprises a charge storage film and is in a vertical opening extending in the vertical direction;
a channel layer on an inner wall of the storage structure in the vertical opening, the channel layer comprising an oxide semiconductor;
a conductive interfacial layer on an inner wall of the channel layer in the vertical opening;
a back-side electrode layer on an inner wall of the conductive interfacial layer in the vertical opening;
a bit line pad connected to a bottom portion of the channel layer in the vertical opening and spaced apart from the back-side electrode layer in the vertical direction;
a spacer insulating layer on the inner wall of the channel layer in the vertical opening, wherein the spacer insulating layer is between the back-side electrode layer and the bit line pad and is between the conductive interfacial layer and the bit line pad;
a bit line connected to the bit line pad;
a common source line on an outer wall of an upper portion of the channel layer;
a first connection via connected to the common source line; and
a second connection via connected to the back-side electrode layer.

20. The memory device of claim 19, wherein the oxide semiconductor comprises at least one of indium gallium zinc oxide, indium aluminum zinc oxide, indium gallium oxide, indium zinc oxide, zinc oxide, zinc tin oxide, indium oxide, titanium oxide, tungsten oxide, or praseodymium chromium manganese oxide,
wherein the back-side electrode layer comprises at least one of tungsten, molybdenum, niobium, nickel, cobalt, copper, palladium, platinum, ruthenium, iridium, gold, silver, chromium, rhodium, indium, tin, magnesium, zinc, beryllium, strontium, barium, titanium nitride, tantalum nitride, tungsten nitride, tin oxide, copper oxide, nickel oxide, or p-type polysilicon, and
wherein the conductive interfacial layer comprises at least one of molybdenum oxide, indium oxide, tungsten oxide, tin oxide, indium tin oxide, indium tungsten oxide, titanium nitride, tantalum nitride, or tungsten nitride.
